(19) United States
(12) Patent Application Publication
(10) Pub. No.: US 2026/0188179 A1
(43) Pub. Date: Jul. 2, 2026

(54) DISPLAY PANEL, DISPLAY DEVICE AND DRIVING CONTROL METHOD

(71) Applicants: Chengdu BOE Optoelectronics Technology Co., Ltd., Chengdu, Sichuan (CN); BOE Technology Group Co., Ltd., Beijing (CN)

(72) Inventors: Changchang LIU, Beijing (CN); Yipeng CHEN, Beijing (CN); Yu WU, Beijing (CN); Ling SHI, Beijing (CN); Bingqiang GUI, Beijing (CN)

(21) Appl. No.: 18/848,501

(22) PCT Filed: Sep. 28, 2023
(86) PCT No.: PCT/CN2023/122484

§ 371 Date: Sep. 18, 2024

(30) Foreign Application Priority Data
Apr. 26, 2023 (CN) 202310462243.6

(51) Int. Cl. G09G 3/32

(52) U.S. Cl. CPC G09G 3/32; G09G 2300/0408; G09G 2300/0426; G09G 2310/0267; G09G 2310/0286; G09G 2330/023

(57) ABSTRACT

The embodiments of the present disclosure provide a display panel, a display device and a driving control method. The display panel includes: a shift register unit and output control signal lines coupled to the shift register unit, where the output control signal lines are disposed between the shift register unit coupled thereto and a display region of the display panel, and the shift register unit includes: a shift register, configured to output a cascade signal through a cascaded output terminal; an output circuit, coupled to the shift register, and configured to control a driving output terminal to output a gate scanning signal according to a signal of an output control signal terminal and a signal of a first reference signal terminal, where the output control signal terminal is coupled to one of the output control signal lines.

### CROSS-REFERENCE TO RELATED APPLICATIONS

This application is a national stage of International Application No. PCT/CN2023/122484, filed on Sep. 28, 2023, which is hereby incorporated by reference in its entirety.

### TECHNICAL FIELD

The present disclosure relates to the field of display technology, and in particular, to a display panel, a display device and a driving control method.

### BACKGROUND

With the rapid development of display technology, display panels present a development trend of high integration level and low cost. Through Gate Driver on Array (GOA) technology, a driving control circuit is integrated on an array substrate of a display panel to form scan driving for the display panel. Currently, the driving control circuit is usually composed of cascaded shift register units.

### SUMMARY

A display panel provided in some embodiments of the present disclosure includes:
a shift register unit and output control signal lines coupled to the shift register unit, where the output control signal lines are disposed between the shift register unit coupled thereto and a display region of the display panel;
the shift register unit includes:
a shift register, configured to output a cascade signal through a cascaded output terminal;
an output circuit, coupled to the shift register, and configured to control a driving output terminal to output a gate scanning signal according to a signal of an output control signal terminal and a signal of a first reference signal terminal, where the output control signal terminal is coupled to one of the output control signal lines.

In some possible embodiments provided in the present disclosure, the output circuit includes: a first output circuit and a second output circuit;
the first output circuit is coupled to the cascaded output terminal or a first node in the shift register, and is configured to, in response to a signal of the cascaded output terminal or the first node, transmit the signal of the output control signal terminal to the driving output terminal;
the second output circuit is coupled to a second node in the shift register, and is configured to, in response to a signal of the second node, transmit the signal of the first reference signal terminal to the driving output terminal.

In some possible embodiments provided in the present disclosure, the first output circuit includes: a first output transistor;
a gate electrode of the first output transistor is coupled to the cascaded output terminal or the first node, a first electrode of the first output transistor is coupled to the output control signal terminal, and a second electrode of the first output transistor is coupled to the driving output terminal.

In some possible embodiments provided in the present disclosure, the second output circuit includes: a second output transistor;
a gate electrode of the second output transistor is coupled to the second node, a first electrode of the second output transistor is coupled to the first reference signal terminal, and a second electrode of the second output transistor is coupled to the driving output terminal.

In some possible embodiments provided in the present disclosure, the shift register includes:
an input sub-circuit, configured to, in response to a signal of a first clock signal terminal, provide a signal of an input signal terminal to a third node;
a control sub-circuit, configured to control signals of the first node and the second node, and provide a signal of the third node to the first node or the second node;
a cascaded sub-circuit, configured to, in response to the signals of the first node and the second node, enable the cascaded output terminal to output the cascade signal.

In some possible embodiments provided in the present disclosure, the input sub-circuit includes: a first transistor;
a gate electrode of the first transistor is coupled to the first clock signal terminal, a first electrode of the first transistor is coupled to the input signal terminal, and a second electrode of the first transistor is coupled to the third node.

In some possible embodiments provided in the present disclosure, the control sub-circuit includes: a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, a first capacitor, a second capacitor, a third capacitor and a fourth capacitor;
a gate electrode of the second transistor is coupled to the third node, a first electrode of the second transistor is coupled to the first clock signal terminal, and a second electrode of the second transistor is coupled to a fourth node;
a gate electrode of the third transistor is coupled to a second reference signal terminal, a first electrode of the third transistor is coupled to the fourth node, and a second electrode of the third transistor is coupled to a gate electrode of the fourth transistor;
a first electrode of the fourth transistor is coupled to a second clock signal terminal, and a second electrode of the fourth transistor is coupled to a first electrode of the fifth transistor;
a gate electrode of the fifth transistor is coupled to the second clock signal terminal, and a second electrode of the fifth transistor is coupled to the first node;
a gate electrode of the sixth transistor is coupled to the first clock signal terminal, a first electrode of the sixth transistor is coupled to the input signal terminal, and a second electrode of the sixth transistor is coupled to a first electrode of the seventh transistor;
a gate electrode of the seventh transistor is coupled to the second reference signal terminal, and a second electrode of the seventh transistor is coupled to a fifth node;
a gate electrode of the eighth transistor is coupled to the fifth node, a first electrode of the eighth transistor is coupled to the fifth node, and a second electrode of the eighth transistor is coupled to the second node;
a gate electrode of the ninth transistor is coupled to the first clock signal terminal, a first electrode of the ninth transistor is coupled to the second reference signal terminal, and a second electrode of the ninth transistor is coupled to a gate electrode of the tenth transistor;
a first electrode of the tenth transistor is coupled to a third reference signal terminal, and a second electrode of the tenth transistor is coupled to a sixth node;
a gate electrode of the eleventh transistor is coupled to the fifth node, a first electrode of the eleventh transistor is coupled to the sixth node, and a second electrode of the eleventh transistor is coupled to the second clock signal terminal;
a gate electrode of the twelfth transistor is coupled to a first electrode of the fifteenth transistor, a first electrode of the twelfth transistor is coupled to the first node, and a second electrode of the twelfth transistor is coupled to a fourth reference signal terminal;
a gate electrode of the thirteenth transistor is coupled to a fifth reference signal terminal, a first electrode of the thirteenth transistor is coupled to the fourth reference signal terminal, and a second electrode of the thirteenth transistor is coupled to a first electrode of the fourteenth transistor;
a gate electrode of the fourteenth transistor is coupled to the first reference signal terminal, and a second electrode of the fourteenth transistor is coupled to the first electrode of the fifteenth transistor;
a gate electrode of the fifteenth transistor is coupled to the first reference signal terminal, the first electrode of the fifteenth transistor is coupled to the third node, and a second electrode of the fifteenth transistor is coupled to the second node;
a first electrode of the first capacitor is coupled to the gate electrode of the fourth transistor, and a second electrode of the first capacitor is coupled to the second electrode of the fourth transistor;
a first electrode of the second capacitor is coupled to the sixth node, and a second electrode of the second capacitor is coupled to the second electrode of the seventh transistor;
a first electrode of the third capacitor is coupled to the fourth reference signal terminal, and a second electrode of the third capacitor is coupled to the first node;
a first electrode of the fourth capacitor is coupled to the cascaded output terminal, and a second electrode of the fourth capacitor is coupled to the first reference signal terminal.

In some possible embodiments provided in the present disclosure, the cascaded sub-circuit includes: a first cascaded transistor and a second cascaded transistor;
a gate electrode of the first cascaded transistor is coupled to the first node, a first electrode of the first cascaded transistor is coupled to a fourth reference signal terminal, and a second electrode of the first cascaded transistor is coupled to the cascaded output terminal;
a gate electrode of the second cascaded transistor is coupled to the second node, a first electrode of the second cascaded transistor is coupled to the cascaded output terminal, and a second electrode of the second cascaded transistor is coupled to the first reference signal terminal.

In some possible embodiments provided in the present disclosure, the input sub-circuit includes: a sixteenth transistor and a seventeenth transistor;
a gate electrode of the sixteenth transistor is coupled to the first clock signal terminal, a first electrode of the sixteenth transistor is coupled to the input signal terminal, and a second electrode of the sixteenth transistor is coupled to a seventh node;
a gate electrode of the seventeenth transistor is coupled to the first clock signal terminal, a first electrode of the seventeenth transistor is coupled to the seventh node, and a second electrode of the seventeenth transistor is coupled to the third node.

In some possible embodiments provided in the present disclosure, the control sub-circuit includes: an eighteenth transistor, a nineteenth transistor, a twentieth transistor, a twenty-first transistor, a twenty-second transistor, a twenty-third transistor, a fifth capacitor and a sixth capacitor;
a gate electrode of the eighteenth transistor is coupled to the cascaded output terminal, a first electrode of the eighteenth transistor is coupled to a third clock signal terminal, and a second electrode of the eighteenth transistor is coupled to a seventh node;
a gate electrode of the nineteenth transistor is coupled to the input signal terminal, a first electrode of the nineteenth transistor is coupled to the first reference signal terminal, and a second electrode of the nineteenth transistor is coupled to the second node;
a gate electrode of the twentieth transistor is coupled to the second node, a first electrode of the twentieth transistor is coupled to the first reference signal terminal, and a second electrode of the twentieth transistor is coupled to an eighth node;
a gate electrode of the twenty-first transistor is coupled to the second node, a first electrode of the twenty-first transistor is coupled to the eighth node, and a second electrode of the twenty-first transistor is coupled to the third node;
a gate electrode of the twenty-second transistor is coupled to the third node, a first electrode of the twenty-second transistor is coupled to the eighth node, and a second electrode of the twenty-second transistor is coupled to a sixth reference signal terminal;
a gate electrode of the twenty-third transistor is coupled to a fourth clock signal terminal, a first electrode of the twenty-third transistor is coupled to the second node, and a second electrode of the twenty-third transistor is coupled to the sixth reference signal terminal;
a first electrode of the fifth capacitor is coupled to the first reference signal terminal, and a second electrode of the fifth capacitor is coupled to the first electrode of the twenty-third transistor;
a first electrode of the sixth capacitor is coupled to the cascaded output terminal, and a second electrode of the sixth capacitor is coupled to the first node.

In some possible embodiments provided in the present disclosure, the cascaded sub-circuit includes: a first cascaded transistor and a second cascaded transistor;
a gate electrode of the first cascaded transistor is coupled to the first node, a first electrode of the first cascaded transistor is coupled to the cascaded output terminal, and a second electrode of the first cascaded transistor is coupled to a third clock signal terminal;
a gate electrode of the second cascaded transistor is coupled to the second node, a first electrode of the second cascaded transistor is coupled to the first reference signal terminal, and a second electrode of the second cascaded transistor is coupled to the cascaded output terminal.

In some possible embodiments provided in the present disclosure, the control sub-circuit includes: a twenty-fourth transistor, a twenty-fifth transistor, a twenty-sixth transistor, a twenty-seventh transistor, a twenty-eighth transistor, a seventh capacitor and an eighth capacitor;
a gate electrode of the twenty-fourth transistor is coupled to the first clock signal terminal, a first electrode of the twenty-fourth transistor is coupled to a seventh reference signal terminal, and a second electrode of the twenty-fourth transistor is coupled to the second node;
a gate electrode of the twenty-fifth transistor is coupled to the third node, a first electrode of the twenty-fifth transistor is coupled to the second node, and a second electrode of the twenty-fifth transistor is coupled to the first clock signal terminal;
a gate electrode of the twenty-sixth transistor is coupled to the second node, a first electrode of the twenty-sixth transistor is coupled to the first reference signal terminal, and a second electrode of the twenty-sixth transistor is coupled to a first electrode of the twenty-seventh transistor;
a gate electrode of the twenty-seventh transistor is coupled to a third clock signal terminal, and a second electrode of the twenty-seventh transistor is coupled to a first electrode of the twenty-eighth transistor;
a gate electrode of the twenty-eighth transistor is coupled to the seventh reference signal terminal, the first electrode of the twenty-eighth transistor is coupled to the third node, and a second electrode of the twenty-eighth transistor is coupled to the first node;
a first electrode of the seventh capacitor is coupled to the first reference signal terminal, and a second electrode of the seventh capacitor is coupled to the second node;
a first electrode of the eighth capacitor is coupled to the cascaded output terminal, and a second electrode of the eighth capacitor is coupled to the first node.

In some possible embodiments provided in the present disclosure, the control sub-circuit further includes: a twenty-eighth transistor;
a first electrode of the twenty-eighth transistor is coupled to the second electrode of the fifth transistor, a second electrode of the twenty-eighth transistor is coupled to the first node, and a gate electrode of the twenty-eighth transistor is coupled to the first reference signal terminal.

A display panel provided in some embodiments of the present disclosure includes:
a base substrate, including a display region and a non-display region,
where the display region includes:
sub-pixels;
scan lines, where each row of the sub-pixels is coupled to at least one of the scan lines,
the non-display region includes:
a gate driving circuit, including shift register units, where a driving output terminal of each of the shift register units is coupled to at least one of the scan lines.

In some possible embodiments provided in the present disclosure, the display panel further includes: output control signal lines coupled to the gate driving circuit, where an extension direction of each of the output control signal lines is same as an arrangement direction of the shift register units.

In some possible embodiments provided in the present disclosure, the output control signal lines are disposed between the gate driving circuit coupled thereto and the display region.

In some possible embodiments provided in the present disclosure, in two adjacent shift register units in the shift register units, an input signal terminal of a latter one of the adjacent shift register units is coupled to a cascaded output terminal of a former one of the adjacent shift register units;
the output control signal lines include: a first output control signal line and a second output control signal line, where the first output control signal line is coupled to output control signal terminals of odd-numbered shift register units, and the second output control signal line is coupled to output control signal terminals of even-numbered shift register units.

In some possible embodiments provided in the present disclosure, in two adjacent shift register units in the shift register units, an input signal terminal of a latter one of the adjacent shift register units is coupled to a cascaded output terminal of a former one of the adjacent shift register units;
the output control signal lines include: a first output control signal line and a second output control signal line; every eight adjacent shift register units in the shift register units constitute one shift register unit group, where the first output control signal line is coupled to output control signal terminals of shift register units in odd-numbered shift register unit groups, and the second output control signal line is coupled to output control signal terminals of shift register units in even-numbered shift register unit groups.

In some possible embodiments provided in the present disclosure, the display panel further includes: output control auxiliary signal lines, where a first insulating layer is provided between the output control auxiliary signal lines and the output control signal lines;
the output control auxiliary signal lines are in one-to-one correspondence with the output control signal lines, and each of the output control auxiliary signal lines and a corresponding one of the output control signal lines are coupled to each other by a first hole through the first insulating layer.

In some possible embodiments provided in the present disclosure, the display panel further includes: clock signal lines coupled to the gate driving circuit, where an extension direction of each of the clock signal lines is same as the arrangement direction of the shift register units.

In some possible embodiments provided in the present disclosure, the clock signal lines are disposed on a side of the gate driving circuit coupled thereto away from the display region.

In some possible embodiments provided in the present disclosure, orthographic projections of the output control signal lines on the base substrate are disposed between orthographic projections of the clock signal lines on the base substrate and the display region.

In some possible embodiments provided in the present disclosure, an orthographic projection of the gate driving circuit on the base substrate is disposed between orthographic projections of the clock signal lines on the base substrate and orthographic projections of the output control signal lines on the base substrate, and
the orthographic projections of the output control signal lines on the base substrate are disposed between the orthographic projection of the gate driving circuit on the base substrate and the display region.

In some possible embodiments provided in the present disclosure, an orthographic projection of a first output transistor on the base substrate is located between an orthographic projection of a first cascaded transistor on the base substrate and the display region.

In some possible embodiments provided in the present disclosure, a width of a channel of a first output transistor is greater than a width of a channel of a first cascaded transistor.

In some possible embodiments provided in the present disclosure, the width of the channel of the first output transistor is not less than 100 μm.

In some possible embodiments provided in the present disclosure, the width of the channel of the first cascaded transistor is not greater than 60 μm.

In some possible embodiments provided in the present disclosure, an orthographic projection of a second output transistor on the base substrate is located between an orthographic projection of a second cascaded transistor on the base substrate and the display region.

In some possible embodiments provided in the present disclosure, a width of a channel of a second output transistor is greater than a width of a channel of a second cascaded transistor.

In some possible embodiments provided in the present disclosure, the width of the channel of the second output transistor is not less than 100 μm.

In some possible embodiments provided in the present disclosure, the width of the channel of the second cascaded transistor is not greater than 60 μm.

A display device provided in some embodiments of the present disclosure includes:
the display panel;
a driving control circuit, coupled to the display panel, and configured to input a first output control signal to output control signal terminals of the shift register units when a full-screen driving mode is determined to be adopted, to cause the shift register units sequentially output gate scanning signals to drive scan lines row by row, and
input a second output control signal to the output control signal terminals of the shift register units when a local driving mode is determined to be adopted, to cause some of the shift register units in the shift register units sequentially output gate scanning signals, and rest of the shift register units output invalid scanning signals.

A driving control method provided in some embodiments of the present disclosure includes:
inputting a first output control signal to output control signal terminals of shift register units when a full-screen driving mode is determined to be adopted, to cause the shift register units sequentially output gate scanning signals to drive scan lines row by row; and
inputting a second output control signal to the output control signal terminals of the shift register units when a local driving mode is determined to be adopted, to cause some of the shift register units in the shift register units sequentially output gate scanning signals, and rest of the shift register units output invalid scanning signals to drive some of the scan lines.

In some possible embodiments provided in the present disclosure, the first output control signal is a fixed voltage signal with a first electrical level.

In some possible embodiments provided in the present disclosure, the second output control signal includes a fixed voltage signal portion with a first electrical level and a fixed voltage signal portion with a second electrical level, the fixed voltage signal portion with the first electrical level is input to some of the shift register units, and the fixed voltage signal portion with the second electrical level is input to rest of the shift register units.

In some possible embodiments provided in the present disclosure, the first output control signal is a clock signal.

In some possible embodiments provided in the present disclosure, the second output control signal includes a clock signal portion and a fixed voltage signal portion with a first electrical level;
the clock signal portion in the second output control signal is input to some of the shift register units, and the fixed voltage signal portion with the first electrical level in the second output control signal is input to rest of the shift register units.

In some possible embodiments provided in the present disclosure, a pulse width of an input signal of an input signal terminal of the shift register unit is 18H, a pulse width of a cascade signal output from a cascaded signal terminal of the shift register unit is 18H, a pulse width of a gate scanning signal output from a driving output terminal of the shift register unit is 18H, and a cascade signal and a valid gate scanning signal output from the shift register unit are shifted backwards by 2H compared with a cascade signal and a valid gate scanning signal output from a previous shift register unit of the shift register units.

### BRIEF DESCRIPTION OF DRAWINGS

The accompanying drawings, which are incorporated in and constitute a part of this specification, illustrate examples consistent with the specification and, together with the description, serve to explain the principle of the specification.

FIG. 1 is a schematic structural diagram of a shift register unit according to an embodiment of the present disclosure;

FIG. 2 is another schematic structural diagram of a shift register unit according to an embodiment of the present disclosure;

FIG. 3 is a schematic structural diagram of a display panel according to an embodiment of the present disclosure;

FIG. 4 is another schematic structural diagram of a display device according to an embodiment of the present disclosure;

FIG. 5 is a flowchart showing a driving control method according to an embodiment of the present disclosure;

FIG. 6 is a signal timing diagram according to an embodiment of the present disclosure;

FIG. 7 is another signal timing diagram according to an embodiment of the present disclosure;

FIG. 8 is another schematic structural diagram of a shift register unit according to an embodiment of the present disclosure;

FIG. 9 is another signal timing diagram according to an embodiment of the present disclosure;

FIG. 10 is another signal timing diagram according to an embodiment of the present disclosure;

FIG. 11 is another schematic structural diagram of a shift register unit according to an embodiment of the present disclosure;

FIG. 12 is another signal timing diagram according to an embodiment of the present disclosure;

FIG. 13 is another signal timing diagram according to an embodiment of the present disclosure;

FIG. 14 is a schematic diagram showing a layout structure of a shift register unit according to an embodiment of the present disclosure;

FIG. 15 is a schematic diagram showing a layout structure of a semiconductor layer according to an embodiment of the present disclosure;

FIG. 16 is a schematic diagram showing a layout structure of a gate conducting layer according to an embodiment of the present disclosure;

FIG. 17 is a schematic diagram showing a layout structure of a capacitor electrode layer according to an embodiment of the present disclosure;

FIG. 18 is a schematic diagram showing a layout structure of a cascaded wiring layer according to an embodiment of the present disclosure;

FIG. 19 is a schematic diagram showing a layout structure of a transmission wiring layer according to an embodiment of the present disclosure;

FIG. 20 is a schematic diagram showing a layout structure of an auxiliary wiring layer according to an embodiment of the present disclosure;

FIG. 21 is another schematic structural diagram of a shift register unit according to an embodiment of the present disclosure;

FIG. 22 is a schematic structural diagram of a display device according to an embodiment of the present disclosure;

FIG. 23 is another signal timing diagram according to an embodiment of the present disclosure;

FIG. 24 is another signal timing diagram according to an embodiment of the present disclosure.

### DETAILED DESCRIPTION

Example embodiments will be described in detail herein, with the illustrations thereof represented in the drawings. When the following descriptions involve the drawings, same numerals in different drawings refer to same or similar elements unless otherwise indicated. The embodiments described in the following examples do not represent all embodiments consistent with the specification. Rather, they are merely examples of apparatuses and methods consistent with some aspects of the specification as detailed in the appended claims.

The terms used in the present disclosure are for the purpose of describing particular embodiments only, and are not intended to limit the present disclosure. Unless otherwise defined, technical or scientific terms used in this specification should have ordinary meaning as understood by one of ordinary skill in the art to which the present disclosure belongs. “First”, “second” and similar words used in the specification and claims do not represent any order, quantity or importance, but are used only to distinguish different components. Likewise, similar words such as “one”, “a” or “an” do not represent a quantity limit, but represent that there is at least one. “Plurality”, “multiple” or “several” means two or more. Unless otherwise indicated, similar words such as “front”, “rear”, “lower” and/or “upper” are only for convenience of description, and are not limited to one position or one spatial orientation. Similar words such as “including” or “comprising” mean that an element or an item appearing before “including” or “comprising” covers elements or items and their equivalents listed after “including” or “comprising”, without excluding other elements or items. Similar words such as “connected” or “coupled” are not limited to physical or mechanical connections, and may include electrical connections, whether direct or indirect.

The terms used in the specification are for the purpose of describing particular embodiments only, and are not intended to limit the present disclosure. Terms determined by “a/an”, “the” and “said” in their singular forms in the specification and the appended claims are also intended to include plural forms unless clearly indicated otherwise in the context. It should also be understood that the term “and/or” as used herein refers to and includes any or all possible combinations of one or more associated listed items.

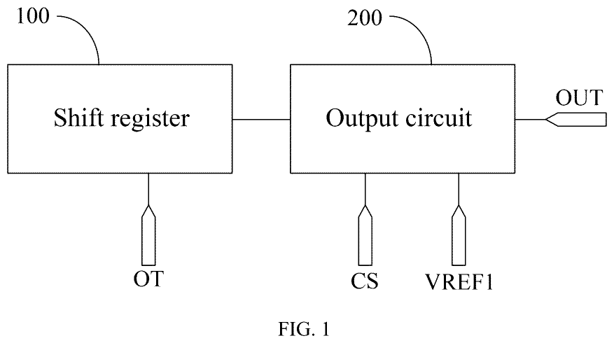

The embodiments of the present disclosure provide a shift register unit, as shown in FIG. 1, including:
a shift register 100, configured to output a cascade signal through a cascaded output terminal OT;
an output circuit 200, coupled to the shift register 100, and configured to control a driving output terminal OUT to output a gate scanning signal according to a signal of an output control signal terminal CS and a signal of a first reference signal terminal VREF1.

The embodiments of the present disclosure provide a shift register unit that outputs a cascade signal by a shift register, and controls a gate scanning signal of a driving output terminal in an output circuit by controlling a signal of an output control signal terminal. When the shift register unit is applied to a display panel, scanning on any region of the display panel can be controlled by controlling the signal of the output control signal terminal, thereby realizing flexible adjustments to refresh frequencies of different regions, saving power consumption, and reducing losses.

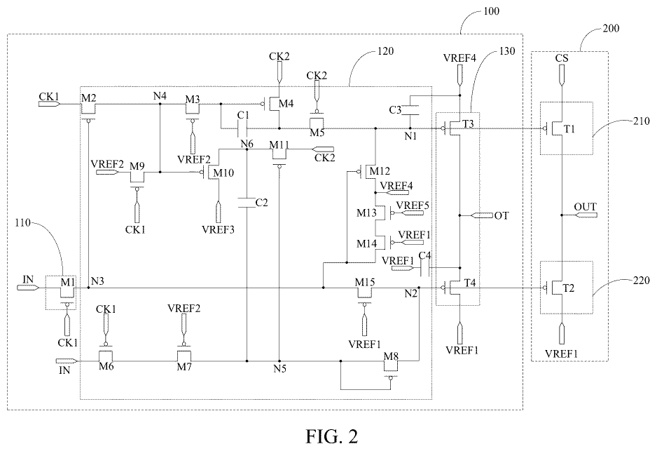

In some embodiments of the present disclosure, as shown in FIG. 2, the output circuit 200 includes: a first output circuit 210 and a second output circuit 220, where the first output circuit 210 is coupled to a first node N1 in the shift register 100, and is configured to, in response to a signal of the first node N1, transmit the signal of the output control signal terminal CS to the driving output terminal OUT; the second output circuit 220 is coupled to a second node N2 in the shift register 100, and is configured to, in response to a signal of the second node N2, transmit the signal of the first reference signal terminal VREF1 to the driving output terminal OUT.

In some embodiments of the present disclosure, as shown in FIG. 2, the first output circuit 210 includes: a first output transistor T1, where a gate electrode of the first output transistor T1 is coupled to the first node N1, a first electrode of the first output transistor T1 is coupled to the output control signal terminal CS, and a second electrode of the first output transistor T1 is coupled to the driving output terminal OUT.

In some embodiments of the present disclosure, as shown in FIG. 2, the second output circuit 220 includes: a second output transistor T2, where a gate electrode of the second output transistor T2 is coupled to the second node N2, a first electrode of the second output transistor T2 is coupled to the first reference signal terminal VREF1, and a second electrode of the second output transistor T2 is coupled to the driving output terminal OUT.

Alternatively, the first output circuit may be coupled to the cascaded output terminal in the shift register, and the first output circuit is configured to, in response to the signal of the cascaded output terminal, transmit the signal of the output control signal terminal to the driving output terminal. Based on this, the gate electrode of the first output transistor is coupled to the cascaded output terminal in the shift register.

In the embodiments of the present disclosure, compared with a manner in which the gate electrode of the first output transistor is coupled to the cascaded output terminal in the shift register, the technical effect corresponding to the manner in which the gate electrode of the first output transistor is coupled to the first node is better. Taking FIG. 2 as an example, the gate electrode of the first output transistor T1 is coupled to the first node N1, and a voltage of a low level signal that the driving output terminal OUT can output is VGL. If the gate electrode of the first output transistor is coupled to the cascaded output terminal in the shift register, since a voltage of a low level signal that the cascaded output terminal can output is only VGL, the voltage of the low level signal that the driving output terminal OUT can output is only VGL-Vth.

In some embodiments of the present disclosure, as shown in FIG. 2, the shift register 100 includes: an input sub-circuit 110, configured to, in response to a signal of a first clock signal terminal CK1, provide a signal of an input signal terminal IN to a third node N3;
a control sub-circuit 120, configured to control signals of the first node N1 and the second node N2, and provide a signal of the third node N3 to the first node N1 or the second node N2;
a cascaded sub-circuit 130, configured to, in response to the signals of the first node N1 and the second node N2, enable the cascaded output terminal OT to output the cascade signal.

In some embodiments of the present disclosure, as shown in FIG. 2, the input sub-circuit 110 includes: a first transistor M1, where a gate electrode of the first transistor M1 is coupled to the first clock signal terminal CK1, a first electrode of the first transistor M1 is coupled to the input signal terminal IN, and a second electrode of the first transistor M1 is coupled to the third node N3.

In some embodiments of the present disclosure, as shown in FIG. 2, the control sub-circuit 120 includes: a second transistor M2, a third transistor M3, a fourth transistor M4, a fifth transistor M5, a sixth transistor M6, a seventh transistor M7, an eighth transistor M8, a ninth transistor M9, a tenth transistor M10, an eleventh transistor M11, a twelfth transistor M12, a thirteenth transistor M13, a fourteenth transistor M14, a fifteenth transistor M15, a first capacitor C1, a second capacitor C2, a third capacitor C3, and a fourth capacitor C4.

A gate electrode of the second transistor M2 is coupled to the third node N3, a first electrode of the second transistor M2 is coupled to the first clock signal terminal CK1, and a second electrode of the second transistor M2 is coupled to a fourth node N4; a gate electrode of the third transistor M3 is coupled to a second reference signal terminal VREF2, a first electrode of the third transistor M3 is coupled to the fourth node N4, and a second electrode of the third transistor M3 is coupled to a gate electrode of the fourth transistor M4; a first electrode of the fourth transistor M4 is coupled to a second clock signal terminal CK2, and a second electrode of the fourth transistor M4 is coupled to a first electrode of the fifth transistor M5; a gate electrode of the fifth transistor M5 is coupled to the second clock signal terminal CK2, and a second electrode of the fifth transistor M5 is coupled to the first node N1; a gate electrode of the sixth transistor M6 is coupled to the first clock signal terminal CK1, a first electrode of the sixth transistor M6 is coupled to the input signal terminal IN, and a second electrode of the sixth transistor M6 is coupled to a first electrode of the seventh transistor M7; a gate electrode of the seventh transistor M7 is coupled to the second reference signal terminal VREF2, and a second electrode of the seventh transistor M7 is coupled to a fifth node N5; a gate electrode of the eighth transistor M8 is coupled to the fifth node N5, a first electrode of the eighth transistor M8 is coupled to the fifth node N5, and a second electrode of the eighth transistor M8 is coupled to the second node N2; a gate electrode of the ninth transistor M9 is coupled to the first clock signal terminal CK1, a first electrode of the ninth transistor M9 is coupled to the second reference signal terminal VREF2, and a second electrode of the ninth transistor M9 is coupled to a gate electrode of the tenth transistor M10; a first electrode of the tenth transistor M10 is coupled to a third reference signal terminal VREF3, and a second electrode of the tenth transistor M10 is coupled to a sixth node N6; a gate electrode of the eleventh transistor M11 is coupled to the fifth node N5, a first electrode of the eleventh transistor M11 is coupled to the sixth node N6, and a second electrode of the eleventh transistor M11 is coupled to the second clock signal terminal CK2; a gate electrode of the twelfth transistor M12 is coupled to a first electrode of the fifteenth transistor M15, a first electrode of the twelfth transistor M12 is coupled to the first node N1, and a second electrode of the twelfth transistor M12 is coupled to a fourth reference signal terminal VREF4; a gate electrode of the thirteenth transistor M13 is coupled to a fifth reference signal terminal VREF5, a first electrode of the thirteenth transistor M13 is coupled to the fourth reference signal terminal VREF4, and a second electrode of the thirteenth transistor M13 is coupled to a first electrode of the fourteenth transistor M14; a gate electrode of the fourteenth transistor M14 is coupled to the first reference signal terminal VREF1, and a second electrode of the fourteenth transistor M14 is coupled to the first electrode of the fifteenth transistor M15; a gate electrode of the fifteenth transistor M15 is coupled to the first reference signal terminal VREF1, the first electrode of the fifteenth transistor M15 is coupled to the third node N3, and a second electrode of the fifteenth transistor M15 is coupled to the second node N2; a first electrode of the first capacitor C1 is coupled to the gate electrode of the fourth transistor M4, and a second electrode of the first capacitor C1 is coupled to the second electrode of the fourth transistor M4; a first electrode of the second capacitor C2 is coupled to the sixth node N6, and a second electrode of the second capacitor C2 is coupled to the second electrode of the seventh transistor M7; a first electrode of the third capacitor C3 is coupled to the fourth reference signal terminal VREF4, and a second electrode of the third capacitor C3 is coupled to the first node N1; a first electrode of the fourth capacitor C4 is coupled to the cascaded output terminal OT, and a second electrode of the fourth capacitor C4 is coupled to the first reference signal terminal VREF1.

In some embodiments of the present disclosure, as shown in FIG. 2, the cascaded sub-circuit 130 includes: a first cascaded transistor T3 and a second cascaded transistor T4, where a gate electrode of the first cascaded transistor T3 is coupled to the first node N1, a first electrode of the first cascaded transistor T3 is coupled to the fourth reference signal terminal VREF4, and a second electrode of the first cascaded transistor T3 is coupled to the cascaded output terminal OT; a gate electrode of the second cascaded transistor T4 is coupled to the second node N2, a first electrode of the second cascaded transistor T4 is coupled to the cascaded output terminal OT, and a second electrode of the second cascaded transistor T4 is coupled to the first reference signal terminal VREF1.

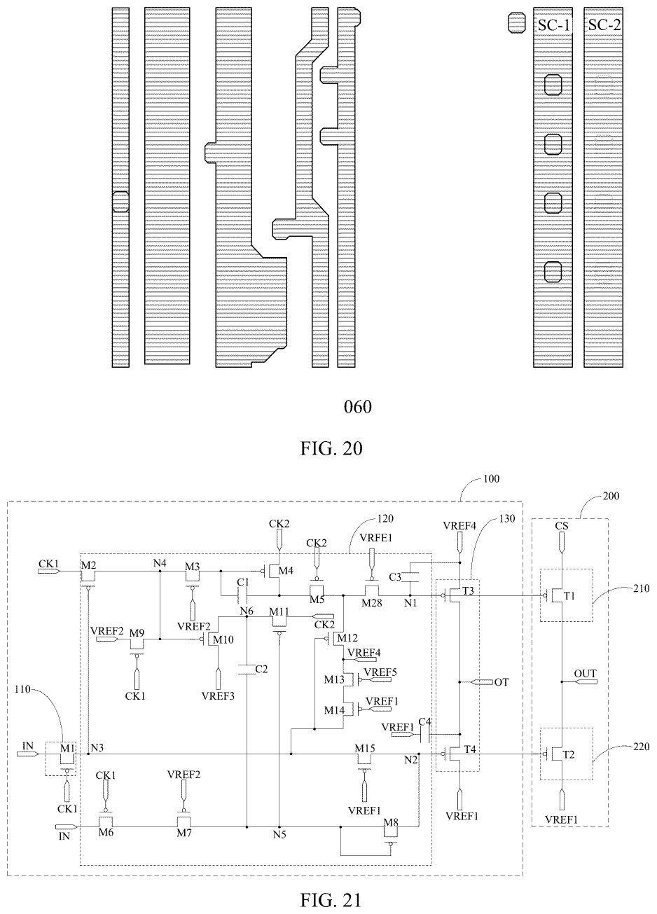

In some embodiments of the present disclosure, as shown in FIG. 21, the control sub-circuit 120 further includes: a twenty-eighth transistor M28.

A first electrode of the twenty-eighth transistor M28 is coupled to the second electrode of the fifth transistor M5, a second electrode of the twenty-eighth transistor M28 is coupled to the first node N1, and a gate electrode of the twenty-eighth transistor M28 is coupled to the first reference signal terminal VREF1.

In an example, a valid pulse signal of the cascade signal output from the cascaded output terminal may be a high level signal; a valid pulse signal of the gate scanning signal output from the driving output terminal may be a high level signal; a valid pulse signal of a first reference signal output from the first reference signal terminal may be a low level signal; a valid pulse signal of a second reference signal output from the second reference signal terminal may be a low level signal; a valid pulse signal of a third reference signal output from the third reference signal terminal may be a high level signal; a valid pulse signal of a fourth reference signal output from the fourth reference signal terminal may be a high level signal. Alternatively, a valid pulse signal of the cascade signal output from the cascaded output terminal may be a low level signal; a valid pulse signal of the gate scanning signal output from the driving output terminal may be a low level signal; a valid pulse signal of a first reference signal output from the first reference signal terminal may be a high level signal; a valid pulse signal of a second reference signal output from the second reference signal terminal may be a high level signal; a valid pulse signal of a third reference signal output from the third reference signal terminal may be a low level signal; a valid pulse signal of a fourth reference signal output from the fourth reference signal terminal may be a low level signal.

In an example, in order to reduce the manufacturing process, all transistors may be P-type transistors, or be N-type transistors, which is not limited herein. Further, the N-type transistors are turned on under the action of a high level signal, and are turned off under the action of a low level signal; the P-type transistors are turned off under the action of a high level signal, and are turned on under the action of a low level signal.

It should be noted that the transistors mentioned in the embodiments of the present disclosure may be Thin Film Transistors (TFTs), or be Metal Oxide Semiconductor Field Effect Transistors (MOSFET), which is not limited herein. In specific implementation, according to different transistor types and input signals, first electrodes of transistors may be used as source electrodes of the transistors, and second electrodes of the transistors may be used as drain electrodes of the transistors, or first electrodes of transistors may be used as drain electrodes of the transistors, and second electrodes of the transistors may be used as source electrodes of the transistors, which is not specifically distinguished herein.

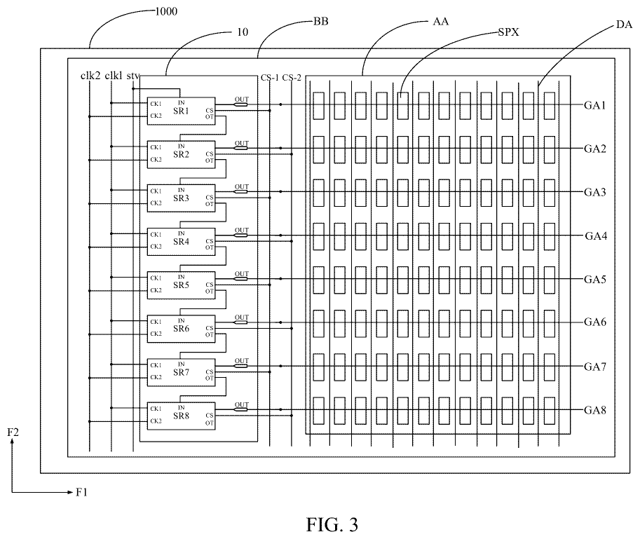

The embodiments of the present disclosure provide a display panel, as shown in FIG. 3, including:
a base substrate 1000, including a display region AA and a non-display region BB.

The display region AA includes:
sub-pixels SPX;
scan lines GA, where each row of the sub-pixels SPX is coupled to at least one of the scan lines GA.

The non-display region BB includes:
a gate driving circuit 10, including shift register units (such as SR1, SR2, SR3, SR4, SR5, SR6, SR7 and SR8 in FIG. 3), where a driving output terminal OUT of each of the shift register units (such as SR1, SR2, SR3, SR4, SR5, SR6, SR7 and SR8 in FIG. 3) is coupled to at least one of the scan line GA.

In some embodiments of the present disclosure, as shown in FIG. 3, the display panel further includes: output control signal lines (such as CS-1 and CS-2 in FIG. 3) coupled to shift register units in the gate driving circuit 10. An output control signal terminal of one shift register unit is coupled to one of the output control signal lines. In addition, an extension direction of each of the output control signal lines (such as CS-1 and CS-2 in FIG. 3) is same as an arrangement direction of the shift register units (such as SR1, SR2, SR3, SR4, SR5, SR6, SR7 and SR8 in FIG. 3). In an example, the extension direction of each of the output control signal lines (such as CS-1 and CS-2 in FIG. 3) is a second direction F2, and the arrangement direction of the shift register units (such as SR1, SR2, SR3, SR4, SR5, SR6, SR7 and SR8 in FIG. 3) is also the second direction F2. F1 in FIG. 3 is a first direction.

In some embodiments of the present disclosure, as shown in FIG. 3, the output control signal lines (such as CS-1 and CS-2 in FIG. 3) are disposed between the gate driving circuit 10 coupled thereto and the display region AA.

In some embodiments of the present disclosure, as shown in FIG. 3, in two adjacent shift register units in the shift register units (such as SR1, SR2, SR3, SR4, SR5, SR6, SR7 and SR8 in FIG. 3), an input signal terminal IN of a latter one of the adjacent shift register units is coupled to a cascaded output terminal OT of a former one of the adjacent shift register units. It should be noted that an input signal terminal IN of a first shift register unit SR1 in the shift register units (such as SR1, SR2, SR3, SR4, SR5, SR6, SR7 and SR8 in FIG. 3) is coupled to a frame start signal line stv.

In some embodiments of the present disclosure, as shown in FIG. 3, the output control signal lines (such as CS-1 and CS-2 in FIG. 3) include: a first output control signal line CS-1 and a second output control signal line CS-2, where the first output control signal line CS-1 is coupled to output control signal terminals CSs of odd-numbered shift register units, and the second output control signal line CS-2 is coupled to output control signal terminals CSs of even-numbered shift register units. In an example, the first output control signal line CS-1 is coupled to output control signal terminals CSs of shift register units SR1, SR3, SR5 and SR7, and the second output control signal line CS-2 is coupled to output control signal terminals CSs of shift register units SR2, SR4, SR6 and SR8.

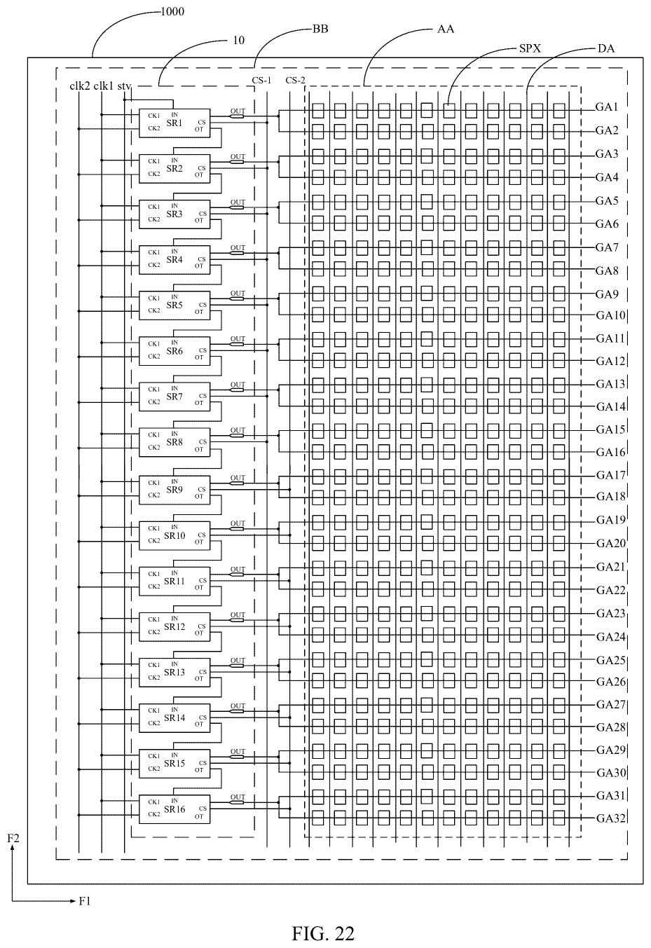

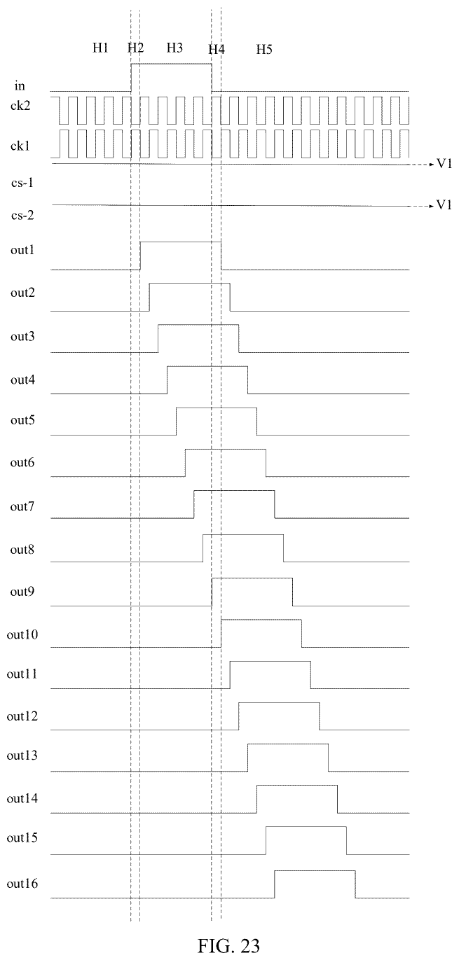

In some embodiments of the present disclosure, as shown in FIG. 22, the output control signal lines (such as CS-1 and CS-2 in FIG. 3) include: a first output control signal line CS-1 and a second output control signal line CS-2, where every eight adjacent shift register units constitute one shift register unit group, the first output control signal line CS-1 is coupled to output control signal terminals CSs of shift register units in odd-numbered shift register unit groups, and the second output control signal line CS-2 is coupled to output control signal terminals CSs of shift register units in even-numbered shift register unit groups. In an example, the first output control signal line CS-1 is coupled to output control signal terminals CSs of shift register units SR1, SR2, SR3, SR4, SR5, SR6, SR7 and SR8, and the second output control signal line CS-2 is coupled to output control signal terminals CSs of shift register units SR9, SR10, SR11, SR12, SR13, SR14, SR15 and SR16.

In some embodiments of the present disclosure, as shown in FIG. 3, the display panel further includes: clock signal lines (such as clk1 and clk2 in FIG. 3) coupled to the gate driving circuit, where an extension direction of each of the clock signal lines (such as clk1 and clk2 in FIG. 3) is same as the arrangement direction of the shift register units.

In some embodiments of the present disclosure, as shown in FIG. 3, the display panel further includes: output control auxiliary signal lines, where a first insulating layer is provided between the output control auxiliary signal lines and the output control signal lines; the output control auxiliary signal lines are in one-to-one correspondence with the output control signal lines, and each of the output control auxiliary signal lines and a corresponding one of the output control signal lines are coupled to each other by a first hole through the first insulating layer.

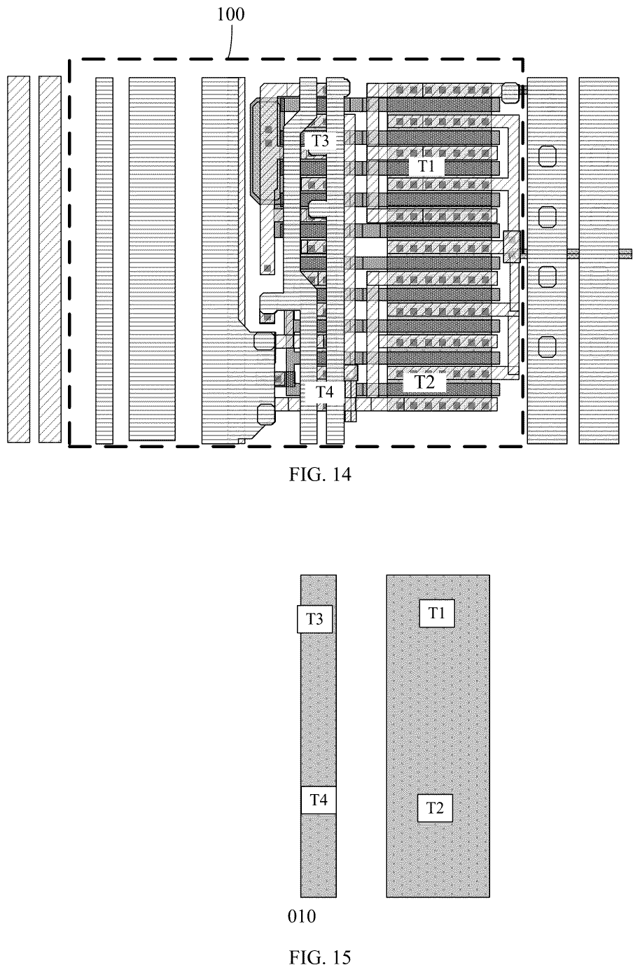

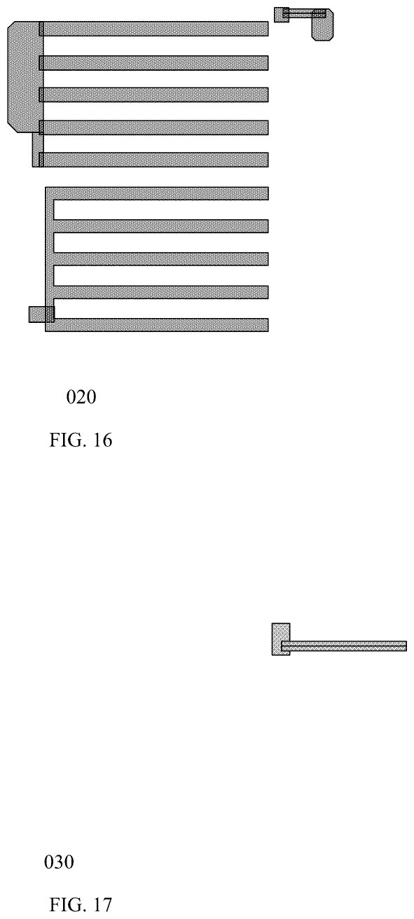

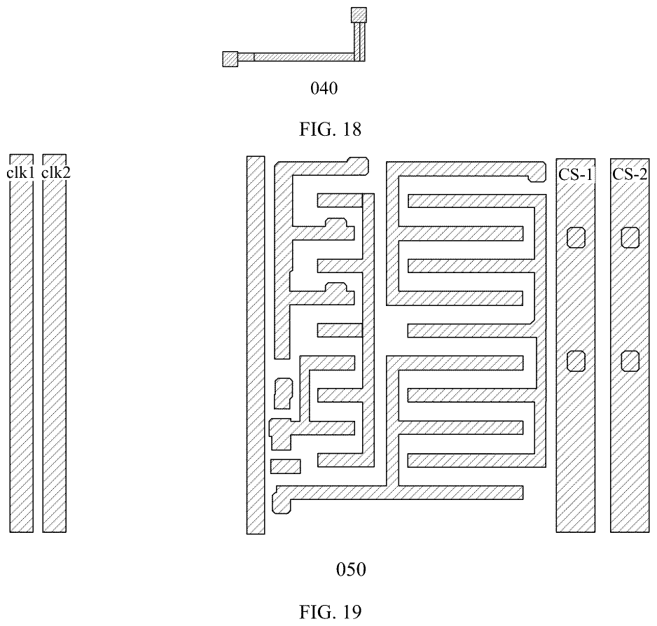

In some embodiments of the present disclosure, as shown in FIG. 14 to FIG. 20, a semiconductor layer 010, a gate conducting layer 020, a capacitor electrode layer 030, a cascaded wiring layer 040, a signal transmission wiring layer 050, and an auxiliary wiring layer 060 are sequentially disposed on the base substrate. Moreover, an insulating layer is disposed between every two adjacent layers in the semiconductor layer 010, the gate conducting layer 020, the capacitor electrode layer 030, the cascaded wiring layer 040, the signal transmission wiring layer 050 and the auxiliary wiring layer 060. In addition, two layers that need to be coupled are coupled to each other through via holes penetrating through the insulating layer.

In an example, the semiconductor layer 010 includes an active layer in each transistor. The semiconductor layer may be formed by patterning a semiconductor material. The semiconductor layer may be configured to manufacture active layers of transistors. In an example, the semiconductor layer may be made of amorphous silicon, polysilicon, an oxide semiconductor material, etc. It should be noted that a source region and a drain region may be conductor regions formed by doping n-type impurities or p-type impurities.

In an example, the gate conducting layer 020 includes a gate electrode and a scan line in each transistor. Gate electrodes of some transistors are reused as one of electrode plates of capacitors.

In an example, the capacitor electrode layer 030 includes another electrode plate in each capacitor. Two electrode plates with opposite areas form the capacitor.

In an example, the cascaded wiring layer 040 includes a cascaded wire configured to couple the input signal terminal IN of the a shift register unit to the cascaded output terminal OT of a previous shift register unit.

In an example, the signal transmission wiring layer 050 includes a clock signal line, an output control signal line, and a source electrode and a drain electrode in each transistor.

In an example, the auxiliary wiring layer 060 includes output control auxiliary signal lines SC-1 and SC-2, and remaining reference signal lines.

In some embodiments of the present disclosure, as shown in FIG. 14, the clock signal lines clk1 and clk2 are disposed on a side of the gate driving circuit coupled thereto away from the display region.

In some embodiments of the present disclosure, as shown in FIG. 14, orthographic projections of the output control signal lines (such as CS-1 and CS-2) on the base substrate are disposed between orthographic projections of the clock signal lines (such as clk1 and clk2) on the base substrate and the display region.

In some embodiments of the present disclosure, as shown in FIG. 14, an orthographic projection of a shift register 100 on the base substrate is disposed between the orthographic projections of the clock signal lines (such as clk1 and clk2) on the base substrate and the orthographic projections of the output control signal lines (such as CS-1 and CS-2) on the base substrate, and the orthographic projections of the output control signal lines (such as CS-1 and CS-2) on the base substrate are disposed between the orthographic projection of the shift register 100 on the base substrate and the display region.

In some embodiments of the present disclosure, as shown in FIG. 14, an orthographic projection of a first output transistor on the base substrate is located between an orthographic projection of a first cascaded transistor on the base substrate and the display region.

In some embodiments of the present disclosure, as shown in FIG. 14, a width of a channel of the first output transistor is greater than a width of a channel of the first cascaded transistor.

In some embodiments of the present disclosure, the width of the channel of the first output transistor is not less than 100 μm.

In some embodiments of the present disclosure, the width of the channel of the first cascaded transistor is not greater than 60 μm.

In some embodiments of the present disclosure, as shown in FIG. 14, an orthographic projection of a second output transistor on the base substrate is located between an orthographic projection of a second cascaded transistor on the base substrate and the display region.

In some embodiments of the present disclosure, as shown in FIG. 14, a width of a channel of the second output transistor is greater than a width of a channel of the second cascaded transistor.

In some embodiments of the present disclosure, the width of the channel of the second output transistor is not less than 100 μm.

In some embodiments of the present disclosure, the width of the channel of the second cascaded transistor is not greater than 60 μm.

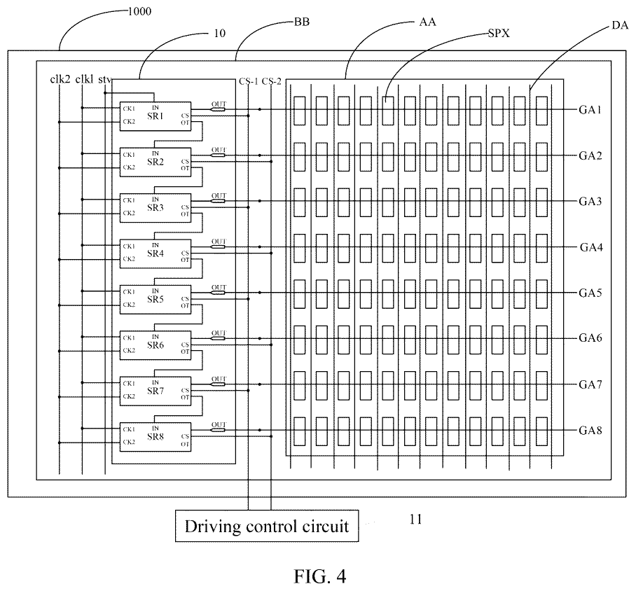

The embodiments of the present disclosure provide a display device, as shown in FIG. 4, including: a display panel;
a driving control circuit 11, coupled to the display panel, and configured to input a first output control signal to output control signal terminals CS of shift register units (such as SR1, SR2, SR3, SR4, SR5, SR6, SR7 and SR8 in FIG. 4) when a full-screen driving mode is determined to be adopted, to cause the shift register units (such as SR1, SR2, SR3, SR4, SR5, SR6, SR7 and SR8 in FIG. 4) sequentially output gate scanning signals to drive scan lines row by row;
input a second output control signal to the output control signal terminals CS of the shift register units (such as SR1, SR2, SR3, SR4, SR5, SR6, SR7 and SR8 in FIG. 4) when a local driving mode is determined to be adopted, to cause some of the shift register units in the shift register units sequentially output gate scanning signals, and rest of the shift register units output invalid scanning signals. In an example, the second output control signal is input to the output control signal terminals CS of the shift register units SR1, SR2, SR3, SR4, SR5, SR6, SR7 and SR8, to cause the shift register units SR1, SR2, SR6, SR7 and SR8 sequentially output gate scanning signals, and rest of the shift register units SR3, SR4 and SR5 output invalid scanning signals.

In an example, the gate scanning signals are high level signals, and the invalid scanning signals are low level signals, or the gate scanning signals are low level signals, and the invalid scanning signals are high level signals, which is not limited herein.

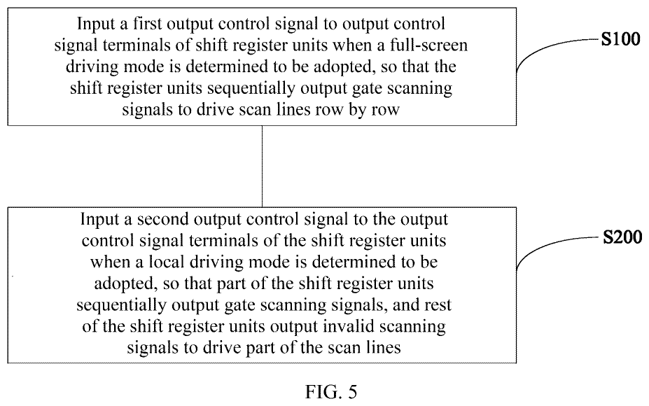

The embodiments of the present disclosure provide a driving control method, as shown in FIG. 5, including:

At S100, a first output control signal is input to output control signal terminals of shift register units when a full-screen driving mode is determined to be adopted, to cause the shift register units sequentially output gate scanning signals to drive scan lines row by row.

At S200, a second output control signal is input to the output control signal terminals of the shift register units when a local driving mode is determined to be adopted, to cause some of the shift register units in the shift register units sequentially output gate scanning signals, and rest of the shift register units output invalid scanning signals to drive some of the scan lines.

In some embodiments of the present disclosure, as shown in FIG. 6, the first output control signal cs1 is a fixed voltage signal with a first electrical level V1. In an example, the fixed voltage signal with the first electrical level V1 is at a high level, or the fixed voltage signal with the first electrical level V1 is at a low level, which is not limited herein.

In an example, in the full-screen driving mode, the first output control signal cs1 is input to the output control signal terminals of the shift register units through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 6.

As shown in FIG. 6, “in” represents an input signal of an input signal terminal IN, ck1 represents a first clock signal of a first clock signal terminal CK1, ck2 represents a second clock signal of a second clock signal terminal CK2, cs1 represents a first output control signal of an output control signal terminal CS, ot1 represents a cascade signal of a cascaded signal terminal OT in a first shift register unit SR1, ot2 represents a cascade signal of a cascaded signal terminal OT in a second shift register unit SR2, ot3 represents a cascade signal of a cascaded signal terminal OT in a third shift register unit SR3, ot4 represents a cascade signal of a cascaded signal terminal OT in a fourth shift register unit SR4, ot5 represents a cascade signal of a cascaded signal terminal OT in a fifth shift register unit SR5, ot6 represents a cascade signal of a cascaded signal terminal OT in a sixth shift register unit SR6, ot7 represents a cascade signal of a cascaded signal terminal OT in a seventh shift register unit SR7, ot8 represents a cascade signal of a cascaded signal terminal OT in an eighth shift register unit SR8, out1 represents a gate scanning signal of a driving output terminal OUT in the first shift register unit SR1, out2 represents a gate scanning signal of a driving output terminal OUT in the second shift register unit SR2, out3 represents a gate scanning signal of a driving output terminal OUT in the third shift register unit SR3, out4 represents a gate scanning signal of a driving output terminal OUT in the fourth shift register unit SR4, out5 represents a gate scanning signal of a driving output terminal OUT in the fifth shift register unit SR5, out6 represents a gate scanning signal of a driving output terminal OUT in the sixth shift register unit SR6, out7 represents a gate scanning signal of a driving output terminal OUT in the seventh shift register unit SR7, and out8 represents a gate scanning signal of a driving output terminal OUT in the eighth shift register unit SR8.

A working process of a shift register unit provided in the embodiments of the present disclosure will be described below by taking a shift register unit structure shown in FIG. 2 as an example with reference to the signal timing diagram shown in FIG. 6.

As shown in FIG. 2, an example in which all transistors are P-type transistors, a valid pulse signal of a first reference signal output from a first reference signal terminal VREF1 is a low level signal, a valid pulse signal of a second reference signal output from a second reference signal terminal VREF2 is a low level signal, a valid pulse signal of a third reference signal output from a third reference signal terminal VREF3 is a high level signal, a valid pulse signal of a fourth reference signal output from a fourth reference signal terminal VREF4 is a high level signal, a valid pulse signal of a fifth reference signal output from a fifth reference signal terminal VREF5 is a high level signal, and a fixed voltage signal with a first electrical level V1 of a first output control signal cs1 is a high level signal is taken for explanation.

Gate electrodes of a third transistor M3 and a seventh transistor M7 are coupled to the second reference signal terminal VREF2, and the second reference signal terminal VREF2 inputs a low level signal. Gate electrodes of a fourteenth transistor M14 and a fifteenth transistor M15 are coupled to the first reference signal terminal VREF1, and the first reference signal terminal VREF1 inputs a low level signal. Therefore, the third transistor M3, the seventh transistor M7, the fourteenth transistor M14 and the fifteenth transistor M15 are in a normally-on state. A gate electrode of a thirteenth transistor M13 is coupled to the fifth reference signal terminal VREF5, and the fifth reference signal terminal VREF5 inputs a high level signal. Therefore, the thirteenth transistor M13 is in a normally-off state. For ease of description, the states of the third transistor M3, the seventh transistor M7, the thirteenth transistor M13, the fourteenth transistor M14, and the fifteenth transistor M15 at any moment will not be analyzed hereinafter.

In a first stage H1, an input signal “in” provides a high level, a first clock signal ck1 provides a low level, and a second clock signal ck2 provides a high level. A first transistor M1 is turned on under the control of the low level of the first clock signal ck1, and the first transistor M1 provides the high level of the input signal “in” to a third node N3. A second transistor M2 is turned off under the control of the high level of the third node N3. A twelfth transistor M12 is turned off under the control of the high level of the third node N3. The fifteenth transistor M15 provides the high level of the third node N3 to a second node N2, and a second cascaded transistor T4 and a second output transistor T2 are turned off. A ninth transistor M9 is turned on under the control of the low level of the first clock signal ck1, and the ninth transistor M9 provides a low level of the second reference signal terminal VREF2 to a fourth node N4. A tenth transistor M10 is turned on under the control of the low level of the fourth node N4, and the tenth transistor M10 provides a high level of the third reference signal terminal VREF3 to a sixth node N6. The third transistor M3 provides the low level of the fourth node N4 to a gate electrode of a fourth transistor M4, and the fourth transistor M4 is turned on. The fourth transistor M4 provides the high level of the second clock signal ck2 to a first electrode of a fifth transistor M5, and the fifth transistor M5 is turned off under the control of the high level of the second clock signal ck2. A first cascaded transistor T3 and a first output transistor T1 are turned off. A sixth transistor M6 is turned on under the control of the low level of the first clock signal ck1, and the sixth transistor M6 and the seventh transistor M7 provide the high level of the input signal “in” to a fifth node N5. An eighth transistor M8 and an eleventh transistor M11 are turned off under the control of the high level of the fifth node N5. A cascade signal output from a cascaded signal terminal OT is maintained at a low level, and a gate scanning signal output from a driving output terminal OUT is maintained at a low level.

In a second stage H2, the input signal “in” provides a low level, the first clock signal ck1 provides a high level, and the second clock signal ck2 provides a low level. The first transistor M1 is turned off under the control of the high level of the first clock signal ck1, and the third node N3 is maintained at a high level. The second transistor M2 is turned off under the control of the high level of the third node N3. The twelfth transistor M12 is turned off under the control of the high level of the third node N3. The fifteenth transistor M15 provides the high level of the third node N3 to the second node N2, and the second cascaded transistor T4 and the second output transistor T2 are turned off. The ninth transistor M9 is turned off under the control of the high level of the first clock signal ck1, and the fourth node N4 is maintained at a low level. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the low level of the second clock signal ck2 to the first electrode of the fifth transistor M5, and the fifth transistor M5 is turned on under the control of the low level of the second clock signal ck2. The fifth transistor M5 provides the low level of the first electrode to a first node N1. The first cascaded transistor T3 and the first output transistor T1 are turned on under the control of the low level of the first node N1. The first cascaded transistor T3 provides a high level of the fourth reference signal terminal VREF4 to the cascaded signal terminal OT. The first output transistor T1 provides a high level of a first output control signal cs1 of an output control signal terminal CS to the driving output terminal OUT. The sixth transistor M6 is turned off under the control of the high level of the first clock signal ck1, and the fifth node N5 is maintained at a high level. The eighth transistor M8 and the eleventh transistor M11 are turned off under the control of the high level of the fifth node N5. The cascade signal output from the cascaded signal terminal OT is maintained at a low level, and the gate scanning signal output from the driving output terminal OUT is maintained at a low level. The cascade signal output from the cascaded signal terminal OT is at a high level, and the gate scanning signal output from the driving output terminal OUT is at a high level.

In a third stage H3, the input signal “in” provides a low level, the first clock signal ck1 provides a low level, and the second clock signal ck2 provides a high level. The first transistor M1 is turned on under the control of the low level of the first clock signal ck1, and the first transistor M1 provides the low level of the input signal “in” to the third node N3. The second transistor M2 is turned on under the control of the low level of the third node N3, and the second transistor M2 provides the low level of the first clock signal ck1 to the fourth node N4. The twelfth transistor M12 is turned on under the control of the low level of the third node N3, and the twelfth transistor M12 provides the high level of the fourth reference signal terminal VREF4 to the first node N1. The first cascaded transistor T3 and the first output transistor T1 are turned off. The fifteenth transistor M15 provides the low level of the third node N3 to the second node N2, and the second cascaded transistor T4 and the second output transistor T2 are turned on under the control of the low level of the second node N2. The second cascaded transistor T4 provides a low level of the first reference signal terminal VREF1 to the cascaded signal terminal OT, and the second output transistor T2 provides the low level of the first reference signal terminal VREF1 to the driving output terminal OUT. The ninth transistor M9 is turned on under the control of the low level of the first clock signal ck1, and the ninth transistor M9 provides the low level of the second reference signal terminal VREF2 to the fourth node N4. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the high level of the second clock signal ck2 to the first electrode of the fifth transistor M5, and the fifth transistor M5 is turned off under the control of the high level of the second clock signal ck2. The first cascaded transistor T3 and the first output transistor T1 are turned off under the control of the high level of the first node N1. The sixth transistor M6 is turned on under the control of the low level of the first clock signal ck1, and the sixth transistor M6 and the seventh transistor M7 provide the low level of the input signal “in” to the fifth node N5. The eighth transistor M8 and the eleventh transistor M11 is turned on under the control of the low level of the fifth node N5. The eighth transistor M8 provides the low level of the fifth node N5 to the second node N2, and the eleventh transistor M11 provides the high level of the second clock signal ck2 to the sixth node N6. The cascade signal output from the cascaded signal terminal OT is maintained at a low level, and the gate scanning signal output from the driving output terminal OUT is maintained at a low level. The cascade signal output from the cascaded signal terminal OT is at a low level, and the gate scanning signal output from the driving output terminal OUT is at a low level.

In subsequent time periods, the shift register unit will repeat the working processes of the stages H1˜H3.

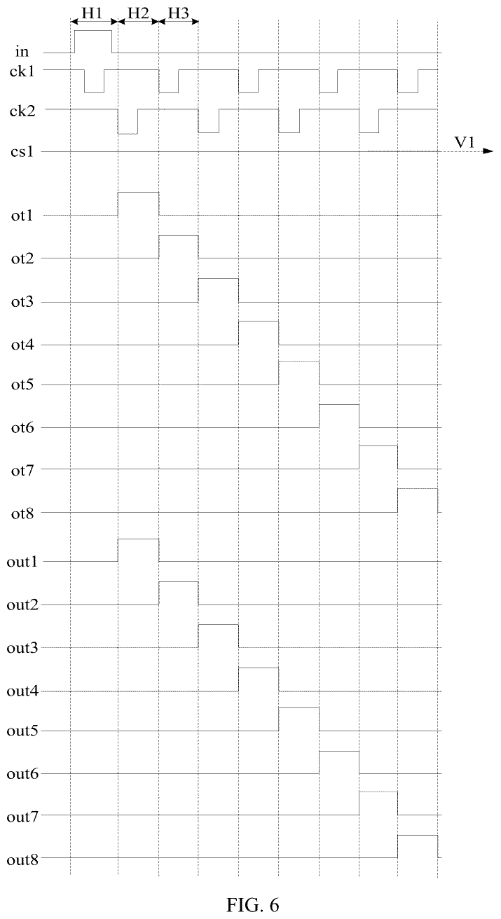

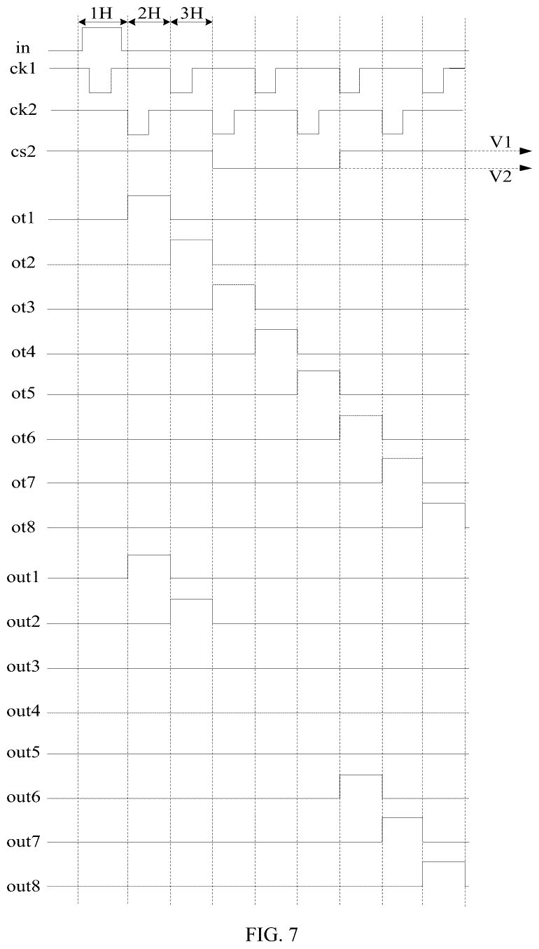

In some embodiments of the present disclosure, as shown in FIG. 7, the second output control signal cs2 includes a fixed voltage signal portion with a first electrical level V1 and a fixed voltage signal portion with a second electrical level V2, where the fixed voltage signal portion with the first electrical level V1 is input to some of the shift register units, and the fixed voltage signal portion with the second electrical level V2 is input to rest of the shift register units.

In an example, the fixed voltage signal portion with the first electrical level V1 of the second output control signal cs2 is input to shift register units SR1, SR2, SR6, SR7 and SR8, and the fixed voltage signal portion with the second electrical level V2 of the second output control signal cs2 is input to shift register units SR3, SR4 and SR5.

In an example, in the local driving mode, the second output control signal cs2 is input to the output control signal terminals of the shift register units through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 7.

As shown in FIG. 7, “in” represents an input signal of an input signal terminal IN, ck1 represents a first clock signal of a first clock signal terminal CK1, ck2 represents a second clock signal of a second clock signal terminal CK2, cs2 represents a second output control signal of an output control signal terminal CS, ot1 represents a cascade signal of a cascaded signal terminal OT in a first shift register unit SR1, ot2 represents a cascade signal of a cascaded signal terminal OT in a second shift register unit SR2, ot3 represents a cascade signal of a cascaded signal terminal OT in a third shift register unit SR3, ot4 represents a cascade signal of a cascaded signal terminal OT in a fourth shift register unit SR4, ot5 represents a cascade signal of a cascaded signal terminal OT in a fifth shift register unit SR5, ot6 represents a cascade signal of a cascaded signal terminal OT in a sixth shift register unit SR6, ot7 represents a cascade signal of a cascaded signal terminal OT in a seventh shift register unit SR7, ot8 represents a cascade signal of a cascaded signal terminal OT in an eighth shift register unit SR8, out1 represents a gate scanning signal of a driving output terminal OUT in the first shift register unit SR1, out2 represents a gate scanning signal of a driving output terminal OUT in the second shift register unit SR2, out3 represents a gate scanning signal of a driving output terminal OUT in the third shift register unit SR3, out4 represents a gate scanning signal of a driving output terminal OUT in the fourth shift register unit SR4, out5 represents a gate scanning signal of a driving output terminal OUT in the fifth shift register unit SR5, out6 represents a gate scanning signal of a driving output terminal OUT in the sixth shift register unit SR6, out7 represents a gate scanning signal of a driving output terminal OUT in the seventh shift register unit SR7, and out8 represents a gate scanning signal of a driving output terminal OUT in the eighth shift register unit SR8.

A working process of a shift register unit provided in the embodiments of the present disclosure will be described below by taking a shift register unit structure shown in FIG. 2 as an example with reference to the signal timing diagram shown in FIG. 7.

As shown in FIG. 2, an example is taken for explanation in which all transistors are P-type transistors, a valid pulse signal of a first reference signal output from a first reference signal terminal VREF1 is a low level signal, a valid pulse signal of a second reference signal output from a second reference signal terminal VREF2 is a low level signal, a valid pulse signal of a third reference signal output from a third reference signal terminal VREF3 is a high level signal, a valid pulse signal of a fourth reference signal output from a fourth reference signal terminal VREF4 is a high level signal, a valid pulse signal of a fifth reference signal output from a fifth reference signal terminal VREF5 is a high level signal, a fixed voltage signal portion with a first electrical level V1 that a second output control signal cs2 has is a high level signal, and a fixed voltage signal portion with a second electrical level V2 that the second output control signal cs2 has is a low level signal.

Gate electrodes of a third transistor M3 and a seventh transistor M7 are coupled to the second reference signal terminal VREF2, and the second reference signal terminal VREF2 inputs a low level signal. Gate electrodes of a fourteenth transistor M14 and a fifteenth transistor M15 are coupled to the first reference signal terminal VREF1, and the first reference signal terminal VREF1 inputs a low level signal. Therefore, the third transistor M3, the seventh transistor M7, the fourteenth transistor M14 and the fifteenth transistor M15 are in a normally-on state. A gate electrode of a thirteenth transistor M13 is coupled to the fifth reference signal terminal VREF5, and the fifth reference signal terminal VREF5 inputs a high level signal. Therefore, the thirteenth transistor M13 is in a normally-off state. For ease of description, the states of the third transistor M3, the seventh transistor M7, the thirteenth transistor M13, the fourteenth transistor M14, and the fifteenth transistor M15 at any moment will not be analyzed hereinafter.

In a first stage H1, an input signal “in” provides a high level, a first clock signal ck provides a low level, and a second clock signal ck2 provides a high level. A first transistor M1 is turned on under the control of the low level of the first clock signal ck1, and the first transistor M1 provides the high level of the input signal “in” to a third node N3. A second transistor M2 is turned off under the control of the high level of the third node N3. A twelfth transistor M12 is turned off under the control of the high level of the third node N3. The fifteenth transistor M15 provides the high level of the third node N3 to a second node N2, and a second cascaded transistor T4 and a second output transistor T2 are turned off. A ninth transistor M9 is turned on under the control of the low level of the first clock signal ck1, and the ninth transistor M9 provides a low level of the second reference signal terminal VREF2 to a fourth node N4. A tenth transistor M10 is turned on under the control of the low level of the fourth node N4, and the tenth transistor M10 provides a high level of the third reference signal terminal VREF3 to a sixth node N6. The third transistor M3 provides the low level of the fourth node N4 to a gate electrode of a fourth transistor M4, and the fourth transistor M4 is turned on. The fourth transistor M4 provides the high level of the second clock signal ck2 to a first electrode of a fifth transistor M5, and the fifth transistor M5 is turned off under the control of the high level of the second clock signal ck2. A first cascaded transistor T3 and a first output transistor T1 are turned off. A sixth transistor M6 is turned on under the control of the low level of the first clock signal ck1, and the sixth transistor M6 and the seventh transistor M7 provide the high level of the input signal “in” to a fifth node N5. An eighth transistor M8 and an eleventh transistor M11 are turned off under the control of the high level of the fifth node N5. A cascade signal output from a cascaded signal terminal OT is maintained at a low level, and a gate scanning signal output from a driving output terminal OUT is maintained at a low level.

In a second stage H2, the input signal “in” provides a low level, the first clock signal ck1 provides a high level, and the second clock signal ck2 provides a low level. The first transistor M1 is turned off under the control of the high level of the first clock signal ck1, and the third node N3 is maintained at a high level. The second transistor M2 is turned off under the control of the high level of the third node N3. The twelfth transistor M12 is turned off under the control of the high level of the third node N3. The fifteenth transistor M15 provides the high level of the third node N3 to the second node N2, and the second cascaded transistor T4 and the second output transistor T2 are turned off. The ninth transistor M9 is turned off under the control of the high level of the first clock signal ck1, and the fourth node N4 is maintained at a low level. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the low level of the second clock signal ck2 to the first electrode of the fifth transistor M5, and the fifth transistor M5 is turned on under the control of the low level of the second clock signal ck2. The fifth transistor M5 provides the low level of the first electrode to a first node N1. The first cascaded transistor T3 and the first output transistor T1 are turned on under the control of the low level of the first node N1. The first cascaded transistor T3 provides a high level of the fourth reference signal terminal VREF4 to the cascaded signal terminal OT. The first output transistor T1 provides a high level of a first output control signal cs1 of an output control signal terminal CS to the driving output terminal OUT. The sixth transistor M6 is turned off under the control of the high level of the first clock signal ck1, and the fifth node N5 is maintained at a high level. The eighth transistor M8 and the eleventh transistor M11 are turned off under the control of the high level of the fifth node N5. The cascade signal output from the cascaded signal terminal OT is maintained at a low level, and the gate scanning signal output from the driving output terminal OUT is maintained at a low level. The cascade signal output from the cascaded signal terminal OT is at a high level, and the gate scanning signal output from the driving output terminal OUT is at a high level.

In a third stage H3, the input signal “in” provides a low level, the first clock signal ck1 provides a low level, and the second clock signal ck2 provides a high level. The first transistor M1 is turned on under the control of the low level of the first clock signal ck1, and the first transistor M1 provides the low level of the input signal “in” to the third node N3. The second transistor M2 is turned on under the control of the low level of the third node N3, and the second transistor M2 provides the low level of the first clock signal ck1 to the fourth node N4. The twelfth transistor M12 is turned on under the control of the low level of the third node N3, and the twelfth transistor M12 provides the high level of the fourth reference signal terminal VREF4 to the first node N1. The first cascaded transistor T3 and the first output transistor T1 are turned off. The fifteenth transistor M15 provides the low level of the third node N3 to the second node N2, and the second cascaded transistor T4 and the second output transistor T2 are turned on under the control of the low level of the second node N2. The second cascaded transistor T4 provides a low level of the first reference signal terminal VREF1 to the cascaded signal terminal OT, and the second output transistor T2 provides the low level of the first reference signal terminal VREF1 to the driving output terminal OUT. The ninth transistor M9 is turned on under the control of the low level of the first clock signal ck1, and the ninth transistor M9 provides the low level of the second reference signal terminal VREF2 to the fourth node N4. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the high level of the second clock signal ck2 to the first electrode of the fifth transistor M5, and the fifth transistor M5 is turned off under the control of the high level of the second clock signal ck2. The first cascaded transistor T3 and the first output transistor T1 are turned off under the control of the high level of the first node N1. The sixth transistor M6 is turned on under the control of the low level of the first clock signal ck1, and the sixth transistor M6 and the seventh transistor M7 provide the low level of the input signal “in” to the fifth node N5. The eighth transistor M8 and the eleventh transistor M11 is turned on under the control of the low level of the fifth node N5. The eighth transistor M8 provides the low level of the fifth node N5 to the second node N2, and the eleventh transistor M11 provides the high level of the second clock signal ck2 to the sixth node N6. The cascade signal output from the cascaded signal terminal OT is maintained at a low level, and the gate scanning signal output from the driving output terminal OUT is maintained at a low level. The cascade signal output from the cascaded signal terminal OT is at a low level, and the gate scanning signal output from the driving output terminal OUT is at a low level.

In subsequent time periods, the shift register unit will repeat the working processes of the stages H1˜H3.

In the embodiments of the present disclosure, by controlling a signal of an output control signal terminal, a gate scanning signal of a driving output terminal in an output circuit is controlled, so that scanning on any region of a display panel is controlled, and non-scanning on any region of the display panel is controlled, which saves power consumption, and reduces losses.

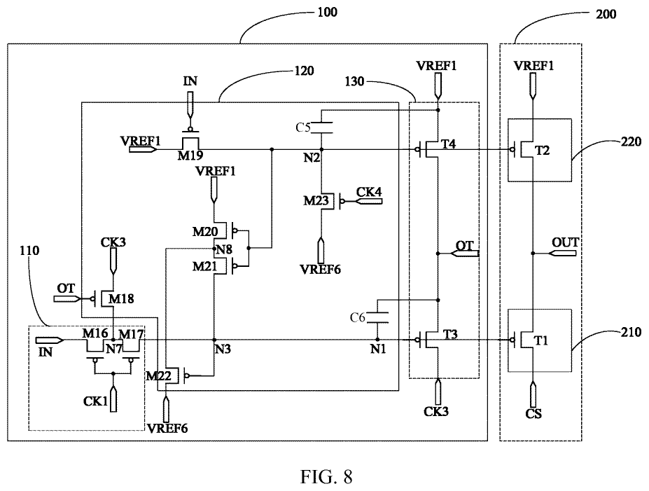

The embodiments of the present disclosure further provide another structural schematic diagram of the shift register unit, as shown in FIG. 8, which is modified for the implementation manners in the above embodiments. Differences between these embodiments and the above embodiments will be described below, and similar contents thereof will not be repeated herein.

In some other embodiments of the present disclosure, as shown in FIG. 8, the input sub-circuit 110 includes: a sixteenth transistor M16 and a seventeenth transistor M17, where a gate electrode of the sixteenth transistor M16 is coupled to the first clock signal terminal CK1, a first electrode of the sixteenth transistor M16 is coupled to the input signal terminal IN, and a second electrode of the sixteenth transistor M16 is coupled to a seventh node N7; a gate electrode of the seventeenth transistor M17 is coupled to the first clock signal terminal CK1, a first electrode of the seventeenth transistor M17 is coupled to the seventh node N7, and a second electrode of the seventeenth transistor M17 is coupled to the third node N3.

In some other embodiments of the present disclosure, as shown in FIG. 8, the control sub-circuit 120 includes: an eighteenth transistor M18, a nineteenth transistor M19, a twentieth transistor M20, a twenty-first transistor M21, a twenty-second transistor M22, a twenty-third transistor M23, a fifth capacitor C5 and a sixth capacitor C6, where a gate electrode of the eighteenth transistor M18 is coupled to the cascaded output terminal OT, a first electrode of the eighteenth transistor M18 is coupled to a third clock signal terminal CK3, and a second electrode of the eighteenth transistor M18 is coupled to the seventh node N7; a gate electrode of the nineteenth transistor M19 is coupled to the input signal terminal IN, a first electrode of the nineteenth transistor M19 is coupled to the first reference signal terminal VREF1, and a second electrode of the nineteenth transistor M19 is coupled to the second node N2; a gate electrode of the twentieth transistor M20 is coupled to the second node N2, a first electrode of the twentieth transistor M20 is coupled to the first reference signal terminal VREF1, and a second electrode of the twentieth transistor M20 is coupled to an eighth node N8; a gate electrode of the twenty-first transistor M21 is coupled to the second node N2, a first electrode of the twenty-first transistor M21 is coupled to the eighth node N8, and a second electrode of the twenty-first transistor M21 is coupled to the third node N3; a gate electrode of the twenty-second transistor M22 is coupled to the third node N3, a first electrode of the twenty-second transistor M22 is coupled to the eighth node N8, and a second electrode of the twenty-second transistor M22 is coupled to a sixth reference signal terminal VREF6; a gate electrode of the twenty-third transistor M23 is coupled to a fourth clock signal terminal CK4, a first electrode of the twenty-third transistor M23 is coupled to the second node N2, and a second electrode of the twenty-third transistor M23 is coupled to the sixth reference signal terminal VREF6; a first electrode of the fifth capacitor C5 is coupled to the first reference signal terminal VREF1, and a second electrode of the fifth capacitor C5 is coupled to the first electrode of the twenty-third transistor M23; a first electrode of the sixth capacitor C6 is coupled to the cascaded output terminal OT, and a second electrode of the sixth capacitor C6 is coupled to the first node N1.

In some other embodiments of the present disclosure, as shown in FIG. 8, the cascaded sub-circuit 130 includes: a first cascaded transistor T3 and a second cascaded transistor T4, where a gate electrode of the first cascaded transistor T3 is coupled to the first node N1, a first electrode of the first cascaded transistor T3 is coupled to the cascaded output terminal OT, and a second electrode of the first cascaded transistor T3 is coupled to the third clock signal terminal CK3; a gate electrode of the second cascaded transistor T4 is coupled to the second node N2, a first electrode of the second cascaded transistor T4 is coupled to the first reference signal terminal VREF1, and a second electrode of the second cascaded transistor T4 is coupled to the cascaded output terminal OT.

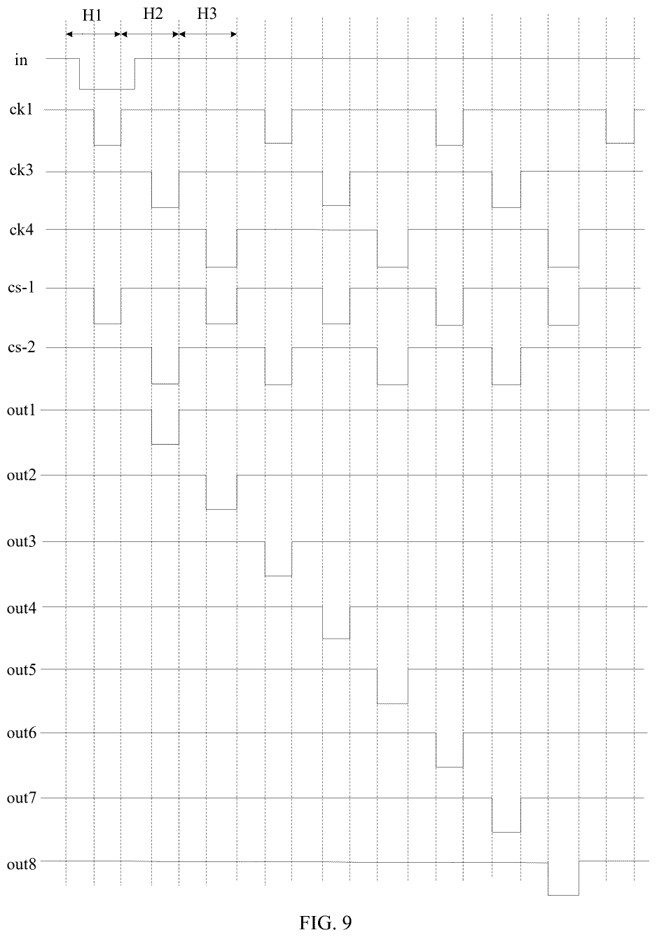

In some other embodiments of the present disclosure, as shown in FIG. 9, first output control signals cs-1 and cs-2 are clock signals.

In an example, in the full-screen driving mode, the first output control signals cs-1 and cs-2 are input to the output control signal terminals of the shift register units respectively through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 9.

As shown in FIG. 9, “in” represents an input signal of an input signal terminal IN, ck1 represents a first clock signal of a first clock signal terminal CK1, ck3 represents a third clock signal of a third clock signal terminal CK3, ck4 represents a fourth clock signal of a fourth clock signal terminal CK4, cs-1 represents a first output control signal on a first output control signal line CS-1, cs-2 represents a first output control signal on a second output control signal line CS-2, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, and out8 represents a gate scanning signal of a driving output terminal OUT in an eighth shift register unit SR8.

A working process of a shift register unit provided in the embodiments of the present disclosure will be described below by taking a shift register unit structure shown in FIG. 8 as an example with reference to the signal timing diagram shown in FIG. 9.

As shown in FIG. 8, an example is taken for explanation in which all transistors are P-type transistors, a valid pulse signal of a first reference signal output from a first reference signal terminal VREF1 is a high level signal, and a valid pulse signal of a sixth reference signal output from a sixth reference signal terminal VREF6 is a low level signal.

In a first stage H1, an input signal “in” provides a low level, a first clock signal ck1 provides a low level, a third clock signal ck3 provides a high level, a fourth clock signal ck4 provides a high level, a first output control signal cs-1 on a first output control signal line CS-1 provides a low level, and a first output control signal cs-2 on a second output control signal line CS-2 provides a high level. A sixteenth transistor M16 is turned on under the control of the low level of the first clock signal ck1, and the sixteenth transistor M16 provides the low level of the input signal “in” to a seventh node N7. A seventeenth transistor M17 is turned on under the control of the low level of the first clock signal ck1, and the seventeenth transistor M17 provides the low level of the seventh node N7 to a third node N3 and a first node N1. A twenty-second transistor M22 is turned on under the control of the low level of the third node N3, and the twenty-second transistor M22 provides a low level of the sixth reference signal terminal VREF6 to an eighth node N8. A nineteenth transistor M19 is turned on under the control of the low level of the input signal “in”, and the nineteenth transistor M19 provides a high level of the first reference signal terminal VREF1 to a second node N2. A twentieth transistor M20 is turned off under the control of the high level of the second node N2. A twenty-first transistor M21 is turned off under the control of the high level of the second node N2. A twenty-third transistor M23 is turned off under the control of the high level of the fourth clock signal ck4. A second cascaded transistor T4 and a second output transistor T2 are turned off under the control of the high level of the second node N2. A first cascaded transistor T3 and a first output transistor T1 are turned on under the control of the low level of the first node N1, the first cascaded transistor T3 provides the high level of the third clock signal ck3 to a cascaded signal terminal OT, and the first output transistor T1 provides a high level signal on an output control signal terminal CS to a driving output terminal OUT. An eighteenth transistor M18 is turned off under the control of a high level of a cascade signal. A cascade signal output from the cascaded signal terminal OT is at a high level, and a gate scanning signal output from the driving output terminal OUT is at a high level.

In a second stage H2, the input signal “in” provides a high level, the first clock signal ck1 provides a high level, the third clock signal ck3 provides a low level, the fourth clock signal ck4 provides a high level, the first output control signal cs-1 on the first output control signal line CS-1 provides a high level, and the first output control signal cs-2 on the second output control signal line CS-2 provides a low level. The sixteenth transistor M16 is turned off under the control of the high level of the first clock signal ck1, and the seventh node N7 is maintained at a low level. The seventeenth transistor M17 is turned off under the control of the high level of the first clock signal ck1, and the third node N3 and the first node N1 are maintained at a low level. The twenty-second transistor M22 is turned on under the control of the low level of the third node N3, and the twenty-second transistor M22 provides the low level of the sixth reference signal terminal VREF6 to the eighth node N8. The nineteenth transistor M19 is turned off under the control of the high level of the input signal “in”, and the second node N2 is maintained at a high level. The twentieth transistor M20 is turned off under the control of the high level of the second node N2. The twenty-first transistor M21 is turned off under the control of the high level of the second node N2. The twenty-third transistor M23 is turned off under the control of the high level of the fourth clock signal ck4. The second cascaded transistor T4 and the second output transistor T2 are turned off under the control of the high level of the second node N2. The first cascaded transistor T3 and the first output transistor T1 are turned on under the control of the low level of the first node N1, the first cascaded transistor T3 provides the low level of the third clock signal ck3 to the cascaded signal terminal OT, and the first output transistor T1 provides a low level signal on the output control signal terminal CS to the driving output terminal OUT. The eighteenth transistor M18 is turned on under the control of a low level of the cascade signal, and the eighteenth transistor M18 provides the low level of the third clock signal ck3 to the seventh node N7. The cascade signal output from the cascaded signal terminal OT is at a low level, and the gate scanning signal output from the driving output terminal OUT is at a low level.

In a third stage H3, the input signal “in” provides a high level, the first clock signal ck1 provides a high level, the third clock signal ck3 provides a high level, the fourth clock signal ck4 provides a low level, the first output control signal cs-1 on the first output control signal line CS-1 provides a low level, and the first output control signal cs-2 on the second output control signal line CS-2 provides a high level. The sixteenth transistor M16 is turned off under the control of the high level of the first clock signal ck1, and the seventh node N7 is maintained at a low level. The seventeenth transistor M17 is turned off under the control of the high level of the first clock signal ck1, and the third node N3 and the first node N1 are maintained at a low level. The twenty-second transistor M22 is turned on under the control of the low level of the third node N3, and the twenty-second transistor M22 provides the low level of the sixth reference signal terminal VREF6 to the eighth node N8. The nineteenth transistor M19 is turned off under the control of the high level of the input signal “in”, and the second node N2 is maintained at a high level. The twentieth transistor M20 is turned off under the control of the high level of the second node N2. The twenty-first transistor M21 is turned off under the control of the high level of the second node N2. The twenty-third transistor M23 is turned on under the control of the low level of the fourth clock signal ck4. The second cascaded transistor T4 and the second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. The first cascaded transistor T3 and the first output transistor T1 are turned on under the control of the low level of the first node N1, the first cascaded transistor T3 provides the high level of the third clock signal ck3 to the cascaded signal terminal OT, and the first output transistor T1 provides the high level signal on the output control signal terminal CS to the driving output terminal OUT. The eighteenth transistor M18 is turned off under the control of the high level of the cascade signal. The cascade signal output from the cascaded signal terminal OT is at a high level, and the gate scanning signal output from the driving output terminal OUT is at a high level.

In subsequent time periods, the shift register unit will repeat the working processes of the stages H1˜H3.

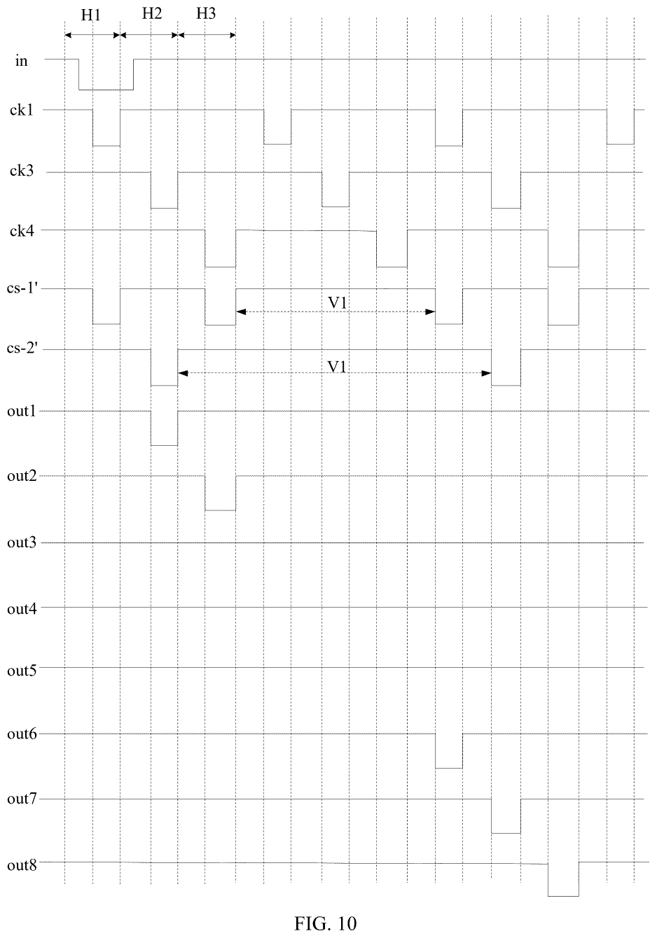

In some other embodiments of the present disclosure, as shown in FIG. 10, second output control signals cs-1′ and cs-2′ include a clock signal portion and a fixed voltage signal portion with a first electrical level V1; the clock signal portion in the second output control signals cs-1′ and cs-2′ is input to some of the shift register units, and the fixed voltage signal portion with the first electrical level in the second output control signals cs-1′ and cs-2′ is input to rest of the shift register units. In an example, the clock signal portion in the second output control signals cs-1′ and cs-2′ is input to shift register units SR1, SR2, SR6, SR7 and SR8, and the fixed voltage signal portion with the first electrical level V1 in the second output control signals cs-1′ and cs-2′ is input to shift register units SR3, SR4 and SR5.

In an example, in the local driving mode, the second output control signals cs-1′ and cs-2′ are input to the output control signal terminals of the shift register units respectively through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 10.

As shown in FIG. 10, “in” represents an input signal of an input signal terminal IN, ck1 represents a first clock signal of a first clock signal terminal CK1, ck3 represents a third clock signal of a third clock signal terminal CK3, ck4 represents a fourth clock signal of a fourth clock signal terminal CK4, cs-1′ represents a second output control signal on a first output control signal line CS-1, cs-2′ represents a second output control signal on a second output control signal line CS-2, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, and out8 represents a gate scanning signal of a driving output terminal OUT in an eighth shift register unit SR8.

A working process of a shift register unit provided in the embodiments of the present disclosure will be described below by taking a shift register unit structure shown in FIG. 8 as an example with reference to the signal timing diagram shown in FIG. 10.

As shown in FIG. 8, an example is taken for explanation in which all transistors are P-type transistors, a valid pulse signal of a first reference signal output from a first reference signal terminal VREF1 is a high level signal, and a valid pulse signal of a sixth reference signal output from a sixth reference signal terminal VREF6 is a low level signal.

In a first stage H1, an input signal “in” provides a low level, a first clock signal ck1 provides a low level, a third clock signal ck3 provides a high level, a fourth clock signal ck4 provides a high level, a second output control signal cs-1′ on a first output control signal line CS-1 provides a low level, and a second output control signal cs-2′ on a second output control signal line CS-2 provides a high level. A sixteenth transistor M16 is turned on under the control of the low level of the first clock signal ck1, and the sixteenth transistor M16 provides the low level of the input signal “in” to a seventh node N7. A seventeenth transistor M17 is turned on under the control of the low level of the first clock signal ck1, and the seventeenth transistor M17 provides the low level of the seventh node N7 to a third node N3 and a first node N1. A twenty-second transistor M22 is turned on under the control of the low level of the third node N3, and the twenty-second transistor M22 provides a low level of the sixth reference signal terminal VREF6 to an eighth node N8. A nineteenth transistor M19 is turned on under the control of the low level of the input signal “in”, and the nineteenth transistor M19 provides a high level of the first reference signal terminal VREF1 to a second node N2. A twentieth transistor M20 is turned off under the control of the high level of the second node N2. A twenty-first transistor M21 is turned off under the control of the high level of the second node N2. A twenty-third transistor M23 is turned off under the control of the high level of the fourth clock signal ck4. A second cascaded transistor T4 and a second output transistor T2 are turned off under the control of the high level of the second node N2. A first cascaded transistor T3 and a first output transistor T1 are turned on under the control of the low level of the first node N1, the first cascaded transistor T3 provides the high level of the third clock signal ck3 to a cascaded signal terminal OT, and the first output transistor T1 provides a high level signal on an output control signal terminal CS to a driving output terminal OUT. An eighteenth transistor M18 is turned off under the control of a high level of a cascade signal. A cascade signal output from the cascaded signal terminal OT is at a high level, and a gate scanning signal output from the driving output terminal OUT is at a high level.

In a second stage H2, the input signal “in” provides a high level, the first clock signal ck1 provides a high level, the third clock signal ck3 provides a low level, the fourth clock signal ck4 provides a high level, the second output control signal cs-1′ on the first output control signal line CS-1 provides a high level, and the second output control signal cs-2′ on the second output control signal line CS-2 provides a low level. The sixteenth transistor M16 is turned off under the control of the high level of the first clock signal ck1, and the seventh node N7 is maintained at a low level. The seventeenth transistor M17 is turned off under the control of the high level of the first clock signal ck1, and the third node N3 and the first node N1 are maintained at a low level. The twenty-second transistor M22 is turned on under the control of the low level of the third node N3, and the twenty-second transistor M22 provides the low level of the sixth reference signal terminal VREF6 to the eighth node N8. The nineteenth transistor M19 is turned off under the control of the high level of the input signal “in”, and the second node N2 is maintained at a high level. The twentieth transistor M20 is turned off under the control of the high level of the second node N2. The twenty-first transistor M21 is turned off under the control of the high level of the second node N2. The twenty-third transistor M23 is turned off under the control of the high level of the fourth clock signal ck4. The second cascaded transistor T4 and the second output transistor T2 are turned off under the control of the high level of the second node N2. The first cascaded transistor T3 and the first output transistor T1 are turned on under the control of the low level of the first node N1, the first cascaded transistor T3 provides the low level of the third clock signal ck3 to the cascaded signal terminal OT, and the first output transistor T1 provides a low level signal on the output control signal terminal CS to the driving output terminal OUT. The eighteenth transistor M18 is turned on under the control of a low level of the cascade signal, and the eighteenth transistor M18 provides the low level of the third clock signal ck3 to the seventh node N7. The cascade signal output from the cascaded signal terminal OT is at a low level, and the gate scanning signal output from the driving output terminal OUT is at a low level.

In a third stage H3, the input signal “in” provides a high level, the first clock signal ck1 provides a high level, the third clock signal ck3 provides a high level, the fourth clock signal ck4 provides a low level, the second output control signal cs-1′ on the first output control signal line CS-1 provides a low level, and the second output control signal cs-2′ on the second output control signal line CS-2 provides a high level. The sixteenth transistor M16 is turned off under the control of the high level of the first clock signal ck1, and the seventh node N7 is maintained at a low level. The seventeenth transistor M17 is turned off under the control of the high level of the first clock signal ck1, and the third node N3 and the first node N1 are maintained at a low level. The twenty-second transistor M22 is turned on under the control of the low level of the third node N3, and the twenty-second transistor M22 provides the low level of the sixth reference signal terminal VREF6 to the eighth node N8. The nineteenth transistor M19 is turned off under the control of the high level of the input signal “in”, and the second node N2 is maintained at a high level. The twentieth transistor M20 is turned off under the control of the high level of the second node N2. The twenty-first transistor M21 is turned off under the control of the high level of the second node N2. The twenty-third transistor M23 is turned on under the control of the low level of the fourth clock signal ck4. The second cascaded transistor T4 and the second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. The first cascaded transistor T3 and the first output transistor T1 are turned on under the control of the low level of the first node N1, the first cascaded transistor T3 provides the high level of the third clock signal ck3 to the cascaded signal terminal OT, and the first output transistor T1 provides the high level signal on the output control signal terminal CS to the driving output terminal OUT. The eighteenth transistor M18 is turned off under the control of the high level of the cascade signal. The cascade signal output from the cascaded signal terminal OT is at a high level, and the gate scanning signal output from the driving output terminal OUT is at a high level.

In subsequent time periods, the shift register unit will repeat the working processes of the stages H1˜H3.

In the embodiments of the present disclosure, by controlling a signal of an output control signal terminal, a gate scanning signal of a driving output terminal in an output circuit is controlled, so that scanning on any region of a display panel is controlled, and non-scanning on any region of the display panel is controlled, which saves power consumption, and reduces losses.

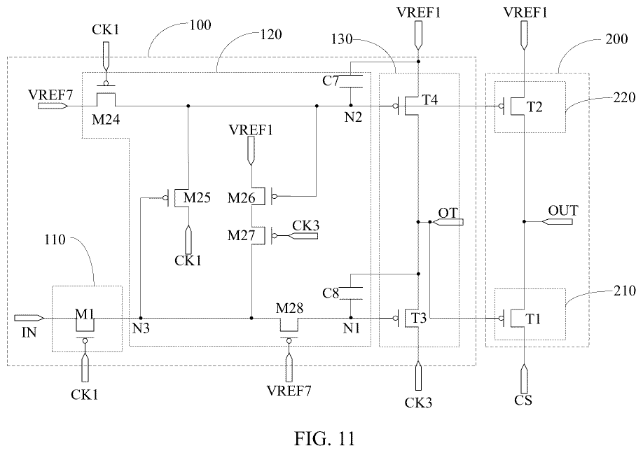

The embodiments of the present disclosure further provide another structural schematic diagram of the shift register unit, as shown in FIG. 11, which is modified for the implementation manners in the above embodiments. Differences between these embodiments and the above embodiments will be described below, and similar contents thereof will not be repeated herein.

In some other embodiments of the present disclosure, as shown in FIG. 11, the first output circuit 210 is coupled to the cascaded output terminal OT in the shift register 100, and is configured to, in response to a signal of the cascaded output terminal OT, transmit the signal of the output control signal terminal CS to the driving output terminal OUT.

In some other embodiments of the present disclosure, as shown in FIG. 11, the gate electrode of the first output transistor T1 is coupled to the cascaded output terminal OT, the first electrode of the first output transistor T1 is coupled to the output control signal terminal CS, and the second electrode of the first output transistor T1 is coupled to the driving output terminal OUT.

In some other embodiments of the present disclosure, as shown in FIG. 11, the control sub-circuit includes: a twenty-fourth transistor M24, a twenty-fifth transistor M25, a twenty-sixth transistor M26, a twenty-seventh transistor M27, a twenty-eighth transistor M28, a seventh capacitor C7 and an eighth capacitor C8, where a gate electrode of the twenty-fourth transistor M24 is coupled to the first clock signal terminal CK1, a first electrode of the twenty-fourth transistor M24 is coupled to a seventh reference signal terminal VREF7, and a second electrode of the twenty-fourth transistor M24 is coupled to the second node N2; a gate electrode of the twenty-fifth transistor M25 is coupled to the third node N3, a first electrode of the twenty-fifth transistor M25 is coupled to the second node N2, and a second electrode of the twenty-fifth transistor M25 is coupled to the first clock signal terminal CK1; a gate electrode of the twenty-sixth transistor M26 is coupled to the second node N2, a first electrode of the twenty-sixth transistor M26 is coupled to the first reference signal terminal VREF1, and a second electrode of the twenty-sixth transistor M26 is coupled to a first electrode of the twenty-seventh transistor M27; a gate electrode of the twenty-seventh transistor M27 is coupled to the third clock signal terminal CK3, and a second electrode of the twenty-seventh transistor M27 is coupled to a first electrode of the twenty-eighth transistor M28; a gate electrode of the twenty-eighth transistor M28 is coupled to the seventh reference signal terminal VREF7, the first electrode of the twenty-eighth transistor M28 is coupled to the third node N3, and a second electrode of the twenty-eighth transistor M28 is coupled to the first node N1; a first electrode of the seventh capacitor C7 is coupled to the first reference signal terminal VREF1, and a second electrode of the seventh capacitor C7 is coupled to the second node N2; a first electrode of the eighth capacitor C8 is coupled to the cascaded output terminal OT, and a second electrode of the eighth capacitor C8 is coupled to the first node N1.

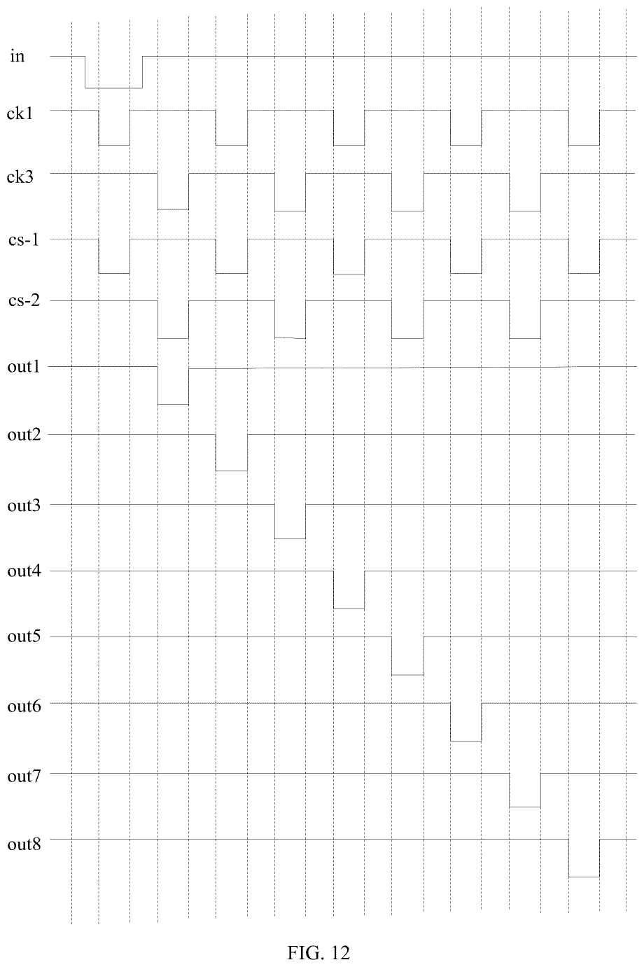

In some other embodiments of the present disclosure, as shown in FIG. 12, first output control signals cs-1 and cs-2 are clock signals.

In an example, in the full-screen driving mode, the first output control signals cs-1 and cs-2 are input to the output control signal terminals of the shift register units respectively through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 12.

As shown in FIG. 12, “in” represents an input signal of an input signal terminal IN, ck1 represents a first clock signal of a first clock signal terminal CK1, ck3 represents a third clock signal of a third clock signal terminal CK3, cs-1 represents a first output control signal on a first output control signal line CS-1, cs-2 represents a first output control signal on a second output control signal line CS-2, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, and out8 represents a gate scanning signal of a driving output terminal OUT in an eighth shift register unit SR8.

A working process of a shift register unit provided in the embodiments of the present disclosure will be described below by taking a shift register unit structure shown in FIG. 11 as an example with reference to the signal timing diagram shown in FIG. 12.

As shown in FIG. 11, an example is taken for explanation in which all transistors are P-type transistors, a valid pulse signal of a first reference signal output from a first reference signal terminal VREF1 is a high level signal, and a valid pulse signal of a seven reference signal output from a seventh reference signal terminal VREF7 is a low level signal.

A twenty-eighth transistor M28 is coupled to the seventh reference signal terminal VREF7, and the seventh reference signal terminal VREF7 inputs a low level signal. Therefore, the twenty-eighth transistor M28 is in a normally-on state. For ease of description, the state of the twenty-eighth transistor M28 at any moment will not be analyzed hereinafter.

In a first stage H1, an input signal “in” provides a low level, a first clock signal ck1 provides a low level, a third clock signal ck3 provides a high level, a first output control signal cs-1 on a first output control signal line CS-1 provides a low level, and a first output control signal cs-2 on a second output control signal line CS-2 provides a high level. A first transistor M1 is turned on under the control of the low level of the first clock signal ck1, and the first transistor M1 provides the low level of the input signal “in” to a third node N3. The twenty-eighth transistor M28 provides the low level of the third node N3 to a first node N1. A first cascaded transistor T3 and a first output transistor T1 are turned on under the control of the low level of the first node N1, the first cascaded transistor T3 provides the high level of the third clock signal ck3 to a cascaded signal terminal OT, and the first output transistor T1 provides a high level signal on an output control signal terminal CS to a driving output terminal OUT. A twenty-fifth transistor M25 is turned on under the control of the low level of the third node N3, and the twenty-fifth transistor M25 provides the low level of the first clock signal ck1 to a second node N2. A twenty-fourth transistor M24 is turned on under the control of the low level of the first clock signal ck1, and the twenty-fourth transistor M24 provides a low level of the seventh reference signal terminal VREF7 to the second node N2. A twenty-sixth transistor M26 is turned on under the control of the low level of the second node N2, and the twenty-sixth transistor M26 provides a high level of the first reference signal terminal VREF1 to a first electrode of a twenty-seventh transistor M27. The twenty-seventh transistor M27 is turned off under the control of the high level of the third clock signal ck3. A second cascaded transistor T4 and a second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. A cascade signal output from the cascaded signal terminal OT is at a high level, and a gate scanning signal output from the driving output terminal OUT is at a high level.

In a second stage H1, the input signal “in” provides a high level, the first clock signal ck1 provides a high level, the third clock signal ck3 provides a low level, the first output control signal cs-1 on the first output control signal line CS-1 provides a high level, and the first output control signal cs-2 on the second output control signal line CS-2 provides a low level. The first transistor M1 is turned off under the control of the high level of the first clock signal ck1, and the third node N3 is maintained at a low level. The twenty-eighth transistor M28 provides the low level of the third node N3 to the first node N1. The first cascaded transistor T3 and the first output transistor T1 are turned on under the control of a low level of the first node N1. The first cascaded transistor T3 provides the low level of the third clock signal ck3 to the cascaded signal terminal OT, and the first output transistor T1 provides a low level signal on the output control signal terminal CS to the driving output terminal OUT. The twenty-fourth transistor M24 is turned off under the control of the high level of the first clock signal ck1, and the second node N2 is maintained at a low level. The twenty-fifth transistor M25 is turned on under the control of the low level of the third node N3, the twenty-fifth transistor M25 provides the high level of the first clock signal ck1 to the second node N2, and the second node N2 is at a high level. The twenty-sixth transistor M26 is turned off under the control of the high level of the second node N2, and the twenty-seventh transistor M27 is turned on under the control of the low level of the third clock signal ck3. The second cascaded transistor T4 and the second output transistor T2 are turned off under the control of the high level of the second node N2. The cascade signal output from the cascaded signal terminal OT is at a low level, and the gate scanning signal output from the driving output terminal OUT is at a low level.

In a third stage H1, the input signal “in” provides a high level, the first clock signal ck1 provides a low level, the third clock signal ck3 provides a high level, the first output control signal cs-1 on the first output control signal line CS-1 provides a low level, and the first output control signal cs-2 on the second output control signal line CS-2 provides a high level. The first transistor M1 is turned on under the control of the low level of the first clock signal ck1, and the first transistor M1 provides the high level of the input signal “in” to the third node N3. The twenty-eighth transistor M28 provides the high level of the third node N3 to the first node N1. The first cascaded transistor T3 and the first output transistor T1 are turned off under the control of the high level of the first node N1. The twenty-fifth transistor M25 is turned off under the control of the high level of the third node N3. The twenty-fourth transistor M24 is turned on under the control of the low level of the first clock signal ck1, and the twenty-fourth transistor M24 provides the low level of the seventh reference signal terminal VREF7 to the second node N2. The twenty-sixth transistor M26 is turned on under the control of the low level of the second node N2, and the twenty-sixth transistor M26 provides the high level of the first reference signal terminal VREF1 to the first electrode of the twenty-seventh transistor M27. The twenty-seventh transistor M27 is turned off under the control of the high level of the third clock signal ck3. The second cascaded transistor T4 and the second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. The cascade signal output from the cascaded signal terminal OT is at a high level, and the gate scanning signal output from the driving output terminal OUT is at a high level.

In subsequent time periods, the shift register unit will repeat the working processes of the stages H1˜H3.

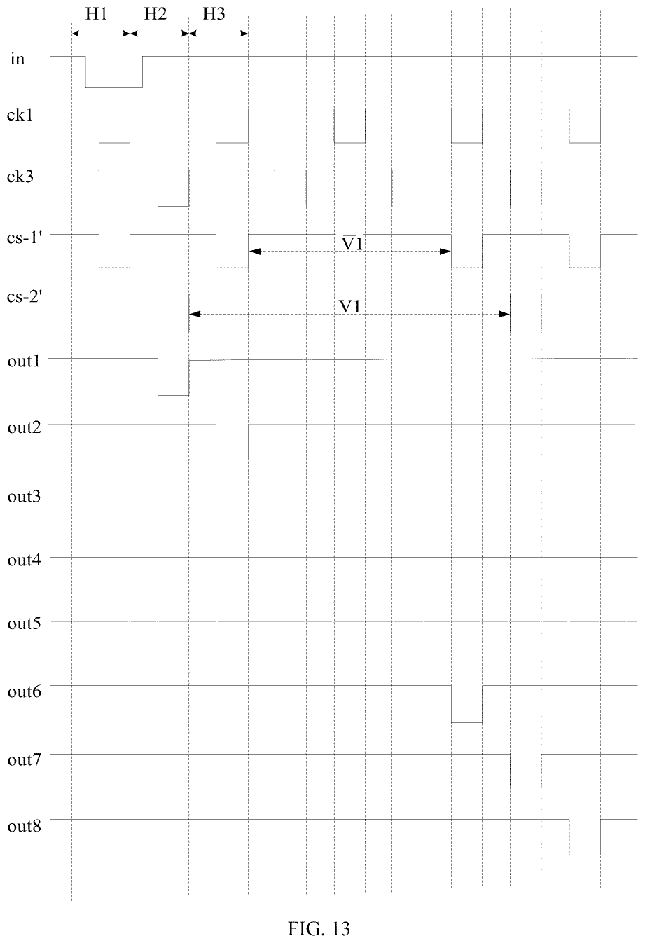

In some other embodiments of the present disclosure, as shown in FIG. 13, second output control signals cs-1′ and cs-2′ include a clock signal portion and a fixed voltage signal portion with a first electrical level V1; the clock signal portion in the second output control signals cs-1′ and cs-2′ is input to some of the shift register units, and the fixed voltage signal portion with the first electrical level in the second output control signals cs-1′ and cs-2′ is input to rest of the shift register units. In an example, the clock signal portion in the second output control signals cs-1′ and cs-2′ is input to shift register units SR1, SR2, SR6, SR7 and SR8, and the fixed voltage signal portion with the first electrical level V1 in the second output control signals cs-1′ and cs-2′ is input to shift register units SR3, SR4 and SR5.

In subsequent time periods, the shift register unit will repeat the working processes of the stages H1˜H3.

In an example, in the local driving mode, the second output control signals cs-1′ and cs-2′ are input to the output control signal terminals of the shift register units respectively through a first output control signal line CS-1 and a second output control signal line CS-2. A signal timing diagram of gate scanning signals out1 to out8 loaded by the scan lines (such as GA1, GA2, GA3, GA4, GA5, GA6, GA7 and GA8 in FIG. 4) is shown in FIG. 13.

As shown in FIG. 13, “in” represents an input signal of an input signal terminal IN, ck1 represents a first clock signal of a first clock signal terminal CK1, ck3 represents a third clock signal of a third clock signal terminal CK3, cs-1′ represents a second output control signal on a first output control signal line CS-1, cs-2′ represents a second output control signal on a second output control signal line CS-2, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, and out8 represents a gate scanning signal of a driving output terminal OUT in an eighth shift register unit SR8.

A working process of a shift register unit provided in the embodiments of the present disclosure will be described below by taking a shift register unit structure shown in FIG. 11 as an example with reference to the signal timing diagram shown in FIG. 13.

As shown in FIG. 11, an example in which all transistors are P-type transistors, a valid pulse signal of a first reference signal output from a first reference signal terminal VREF1 is a high level signal, and a valid pulse signal of a seven reference signal output from a seventh reference signal terminal VREF7 is a low level signal is taken for explanation.

A twenty-eighth transistor M28 is coupled to the seventh reference signal terminal VREF7, and the seventh reference signal terminal VREF7 inputs a low level signal. Therefore, the twenty-eighth transistor M28 is in a normally-on state. For ease of description, the state of the twenty-eighth transistor M28 at any moment will not be analyzed hereinafter.

In a first stage H1, an input signal “in” provides a low level, a first clock signal ck1 provides a low level, a third clock signal ck3 provides a high level, a first output control signal cs-1 on a first output control signal line CS-1 provides a low level, and a first output control signal cs-2 on a second output control signal line CS-2 provides a high level. A first transistor M1 is turned on under the control of the low level of the first clock signal ck1, and the first transistor M1 provides the low level of the input signal “in” to a third node N3. The twenty-eighth transistor M28 provides the low level of the third node N3 to a first node N1. A first cascaded transistor T3 and a first output transistor T1 are turned on under the control of the low level of the first node N1, the first cascaded transistor T3 provides the high level of the third clock signal ck3 to a cascaded signal terminal OT, and the first output transistor T1 provides a high level signal on an output control signal terminal CS to a driving output terminal OUT. A twenty-fifth transistor M25 is turned on under the control of the low level of the third node N3, and the twenty-fifth transistor M25 provides the low level of the first clock signal ck1 to a second node N2. A twenty-fourth transistor M24 is turned on under the control of the low level of the first clock signal ck1, and the twenty-fourth transistor M24 provides a low level of the seventh reference signal terminal VREF7 to the second node N2. A twenty-sixth transistor M26 is turned on under the control of the low level of the second node N2, and the twenty-sixth transistor M26 provides a high level of the first reference signal terminal VREF1 to a first electrode of a twenty-seventh transistor M27. The twenty-seventh transistor M27 is turned off under the control of the high level of the third clock signal ck3. A second cascaded transistor T4 and a second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. A cascade signal output from the cascaded signal terminal OT is at a high level, and a gate scanning signal output from the driving output terminal OUT is at a high level.

In a second stage H1, the input signal “in” provides a high level, the first clock signal ck1 provides a high level, the third clock signal ck3 provides a low level, the first output control signal cs-1 on the first output control signal line CS-1 provides a high level, and the first output control signal cs-2 on the second output control signal line CS-2 provides a low level. The first transistor M1 is turned off under the control of the high level of the first clock signal ck1, and the third node N3 is maintained at a low level. The twenty-eighth transistor M28 provides the low level of the third node N3 to the first node N1. The first cascaded transistor T3 and the first output transistor T1 are turned on under the control of a low level of the first node N1. The first cascaded transistor T3 provides the low level of the third clock signal ck3 to the cascaded signal terminal OT, and the first output transistor T1 provides a low level signal on the output control signal terminal CS to the driving output terminal OUT. The twenty-fourth transistor M24 is turned off under the control of the high level of the first clock signal ck1, and the second node N2 is maintained at a low level. The twenty-fifth transistor M25 is turned on under the control of the low level of the third node N3, the twenty-fifth transistor M25 provides the high level of the first clock signal ck1 to the second node N2, and the second node N2 is at a high level. The twenty-sixth transistor M26 is turned off under the control of the high level of the second node N2, and the twenty-seventh transistor M27 is turned on under the control of the low level of the third clock signal ck3. The second cascaded transistor T4 and the second output transistor T2 are turned off under the control of the high level of the second node N2. The cascade signal output from the cascaded signal terminal OT is at a low level, and the gate scanning signal output from the driving output terminal OUT is at a low level.

In a third stage H1, the input signal “in” provides a high level, the first clock signal ck1 provides a low level, the third clock signal ck3 provides a high level, the first output control signal cs-1 on the first output control signal line CS-1 provides a low level, and the first output control signal cs-2 on the second output control signal line CS-2 provides a high level. The first transistor M1 is turned on under the control of the low level of the first clock signal ck1, and the first transistor M1 provides the high level of the input signal “in” to the third node N3. The twenty-eighth transistor M28 provides the high level of the third node N3 to the first node N1. The first cascaded transistor T3 and the first output transistor T1 are turned off under the control of the high level of the first node N1. The twenty-fifth transistor M25 is turned off under the control of the high level of the third node N3. The twenty-fourth transistor M24 is turned on under the control of the low level of the first clock signal ck1, and the twenty-fourth transistor M24 provides the low level of the seventh reference signal terminal VREF7 to the second node N2. The twenty-sixth transistor M26 is turned on under the control of the low level of the second node N2, and the twenty-sixth transistor M26 provides the high level of the first reference signal terminal VREF1 to the first electrode of the twenty-seventh transistor M27. The twenty-seventh transistor M27 is turned off under the control of the high level of the third clock signal ck3. The second cascaded transistor T4 and the second output transistor T2 are turned on under the control of the low level of the second node N2, the second cascaded transistor T4 provides the high level of the first reference signal terminal VREF1 to the cascaded signal terminal OT, and the second output transistor T2 provides the high level of the first reference signal terminal VREF1 to the driving output terminal OUT. The cascade signal output from the cascaded signal terminal OT is at a high level, and the gate scanning signal output from the driving output terminal OUT is at a high level.

In subsequent time periods, the shift register unit will repeat the working processes of the stages H1˜H3.

As shown in FIG. 6, “in” represents an input signal of an input signal terminal IN, ck1 represents a first clock signal of a first clock signal terminal CK1, ck2 represents a second clock signal of a second clock signal terminal CK2, cs1 represents a first output control signal of an output control signal terminal CS, ot1 represents a cascade signal of a cascaded signal terminal OT in a first shift register unit SR1, ot2 represents a cascade signal of a cascaded signal terminal OT in a second shift register unit SR2, ot3 represents a cascade signal of a cascaded signal terminal OT in a third shift register unit SR3, ot4 represents a cascade signal of a cascaded signal terminal OT in a fourth shift register unit SR4, ot5 represents a cascade signal of a cascaded signal terminal OT in a fifth shift register unit SR5, ot6 represents a cascade signal of a cascaded signal terminal OT in a sixth shift register unit SR6, ot7 represents a cascade signal of a cascaded signal terminal OT in a seventh shift register unit SR7, ot8 represents a cascade signal of a cascaded signal terminal OT in an eighth shift register unit SR8, out1 represents a gate scanning signal of a driving output terminal OUT in the first shift register unit SR1, out2 represents a gate scanning signal of a driving output terminal OUT in the second shift register unit SR2, out3 represents a gate scanning signal of a driving output terminal OUT in the third shift register unit SR3, out4 represents a gate scanning signal of a driving output terminal OUT in the fourth shift register unit SR4, out5 represents a gate scanning signal of a driving output terminal OUT in the fifth shift register unit SR5, out6 represents a gate scanning signal of a driving output terminal OUT in the sixth shift register unit SR6, out7 represents a gate scanning signal of a driving output terminal OUT in the seventh shift register unit SR7, and out8 represents a gate scanning signal of a driving output terminal OUT in the eighth shift register unit SR8.

A working process of a shift register unit provided in the embodiments of the present disclosure will be described below by taking a shift register unit structure shown in FIG. 21 as an example with reference to the signal timing diagram shown in FIG. 6.

As shown in FIG. 21, an example is taken for explanation in which all transistors are P-type transistors, a valid pulse signal of a first reference signal output from a first reference signal terminal VREF1 is a low level signal, a valid pulse signal of a second reference signal output from a second reference signal terminal VREF2 is a low level signal, a valid pulse signal of a third reference signal output from a third reference signal terminal VREF3 is a high level signal, a valid pulse signal of a fourth reference signal output from a fourth reference signal terminal VREF4 is a high level signal, a valid pulse signal of a fifth reference signal output from a fifth reference signal terminal VREF5 is a high level signal, and a fixed voltage signal with a first electrical level V1 that a first output control signal cs1 has is a high level signal.

Gate electrodes of a third transistor M3 and a seventh transistor M7 are coupled to the second reference signal terminal VREF2, and the second reference signal terminal VREF2 inputs a low level signal. Gate electrodes of a fourteenth transistor M14, a fifteenth transistor M15 and a twenty-eighth transistor M28 are coupled to the first reference signal terminal VREF1, and the first reference signal terminal VREF1 inputs a low level signal. Therefore, the third transistor M3, the seventh transistor M7, the fourteenth transistor M14, the fifteenth transistor M15 and the twenty-eighth transistor M28 are in a normally-on state. A gate electrode of a thirteenth transistor M13 is coupled to the fifth reference signal terminal VREF5, and the fifth reference signal terminal VREF5 inputs a high level signal. Therefore, the thirteenth transistor M13 is in a normally-off state. For ease of description, the states of the third transistor M3, the seventh transistor M7, the thirteenth transistor M13, the fourteenth transistor M14, and the fifteenth transistor M15 at any moment will not be analyzed hereinafter.

In a first stage H1, an input signal “in” provides a high level, a first clock signal ck1 provides a low level, and a second clock signal ck2 provides a high level. A first transistor M1 is turned on under the control of the low level of the first clock signal ck1, and the first transistor M1 provides the high level of the input signal “in” to a third node N3. A second transistor M2 is turned off under the control of the high level of the third node N3. A twelfth transistor M12 is turned off under the control of the high level of the third node N3. The fifteenth transistor M15 provides the high level of the third node N3 to a second node N2, and a second cascaded transistor T4 and a second output transistor T2 are turned off. A ninth transistor M9 is turned on under the control of the low level of the first clock signal ck1, and the ninth transistor M9 provides a low level of the second reference signal terminal VREF2 to a fourth node N4. A tenth transistor M10 is turned on under the control of the low level of the fourth node N4, and the tenth transistor M10 provides a high level of the third reference signal terminal VREF3 to a sixth node N6. The third transistor M3 provides the low level of the fourth node N4 to a gate electrode of a fourth transistor M4, and the fourth transistor M4 is turned on. The fourth transistor M4 provides the high level of the second clock signal ck2 to a first electrode of a fifth transistor M5, and the fifth transistor M5 is turned off under the control of the high level of the second clock signal ck2. A first cascaded transistor T3 and a first output transistor T1 are turned off. A sixth transistor M6 is turned on under the control of the low level of the first clock signal ck1, and the sixth transistor M6 and the seventh transistor M7 provide the high level of the input signal “in” to a fifth node N5. An eighth transistor M8 and an eleventh transistor M11 are turned off under the control of the high level of the fifth node N5. A cascade signal output from a cascaded signal terminal OT is maintained at a low level, and a gate scanning signal output from a driving output terminal OUT is maintained at a low level.

In a second stage H2, the input signal “in” provides a low level, the first clock signal ck1 provides a high level, and the second clock signal ck2 provides a low level. The first transistor M1 is turned off under the control of the high level of the first clock signal ck1, and the third node N3 is maintained at a high level. The second transistor M2 is turned off under the control of the high level of the third node N3. The twelfth transistor M12 is turned off under the control of the high level of the third node N3. The fifteenth transistor M15 provides the high level of the third node N3 to the second node N2, and the second cascaded transistor T4 and the second output transistor T2 are turned off. The ninth transistor M9 is turned off under the control of the high level of the first clock signal ck1, and the fourth node N4 is maintained at a low level. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the low level of the second clock signal ck2 to the first electrode of the fifth transistor M5, and the fifth transistor M5 is turned on under the control of the low level of the second clock signal ck2. The fifth transistor M5 provides the low level of the first electrode to a first node N1. The first cascaded transistor T3 and the first output transistor T1 are turned on under the control of the low level of the first node N1. The first cascaded transistor T3 provides a high level of the fourth reference signal terminal VREF4 to the cascaded signal terminal OT. The first output transistor T1 provides a high level of a first output control signal cs1 of an output control signal terminal CS to the driving output terminal OUT. The sixth transistor M6 is turned off under the control of the high level of the first clock signal ck1, and the fifth node N5 is maintained at a high level. The eighth transistor M8 and the eleventh transistor M11 are turned off under the control of the high level of the fifth node N5. The cascade signal output from the cascaded signal terminal OT is maintained at a low level, and the gate scanning signal output from the driving output terminal OUT is maintained at a low level. The cascade signal output from the cascaded signal terminal OT is at a high level, and the gate scanning signal output from the driving output terminal OUT is at a high level.

In a third stage H3, the input signal “in” provides a low level, the first clock signal ck1 provides a low level, and the second clock signal ck2 provides a high level. The first transistor M1 is turned on under the control of the low level of the first clock signal ck1, and the first transistor M1 provides the low level of the input signal “in” to the third node N3. The second transistor M2 is turned on under the control of the low level of the third node N3, and the second transistor M2 provides the low level of the first clock signal ck1 to the fourth node N4. The twelfth transistor M12 is turned on under the control of the low level of the third node N3, and the twelfth transistor M12 provides the high level of the fourth reference signal terminal VREF4 to the first node N1. The first cascaded transistor T3 and the first output transistor T1 are turned off. The fifteenth transistor M15 provides the low level of the third node N3 to the second node N2, and the second cascaded transistor T4 and the second output transistor T2 are turned on under the control of the low level of the second node N2. The second cascaded transistor T4 provides a low level of the first reference signal terminal VREF1 to the cascaded signal terminal OT, and the second output transistor T2 provides the low level of the first reference signal terminal VREF1 to the driving output terminal OUT. The ninth transistor M9 is turned on under the control of the low level of the first clock signal ck1, and the ninth transistor M9 provides the low level of the second reference signal terminal VREF2 to the fourth node N4. The tenth transistor M10 is turned on under the control of the low level of the fourth node N4, and the tenth transistor M10 provides the high level of the third reference signal terminal VREF3 to the sixth node N6. The third transistor M3 provides the low level of the fourth node N4 to the gate electrode of the fourth transistor M4, and the fourth transistor M4 is turned on. The fourth transistor M4 provides the high level of the second clock signal ck2 to the first electrode of the fifth transistor M5, and the fifth transistor M5 is turned off under the control of the high level of the second clock signal ck2. The first cascaded transistor T3 and the first output transistor T1 are turned off under the control of the high level of the first node N1. The sixth transistor M6 is turned on under the control of the low level of the first clock signal ck1, and the sixth transistor M6 and the seventh transistor M7 provide the low level of the input signal “in” to the fifth node N5. The eighth transistor M8 and the eleventh transistor M11 is turned on under the control of the low level of the fifth node N5. The eighth transistor M8 provides the low level of the fifth node N5 to the second node N2, and the eleventh transistor M11 provides the high level of the second clock signal ck2 to the sixth node N6. The cascade signal output from the cascaded signal terminal OT is maintained at a low level, and the gate scanning signal output from the driving output terminal OUT is maintained at a low level. The cascade signal output from the cascaded signal terminal OT is at a low level, and the gate scanning signal output from the driving output terminal OUT is at a low level.

In subsequent time periods, the shift register unit will repeat the working processes of the stages H1˜H3.

As shown in FIG. 21 and FIG. 22, the output control signal lines (such as CS-1 and CS-2 in FIG. 3) include: a first output control signal line CS-1 and a second output control signal line CS-2, where every eight adjacent shift register units in the shift register units constitute one shift register unit group, the first output control signal line CS-1 is coupled to output control signal terminals CSs of shift register units in odd-numbered shift register unit groups, and the second output control signal line CS-2 is coupled to output control signal terminals CSs of shift register units in even-numbered shift register unit groups. In an example, the first output control signal line CS-1 is coupled to output control signal terminals CSs of shift register units SR1, SR2, SR3, SR4, SR5, SR6, SR7 and SR8, and the second output control signal line CS-2 is coupled to output control signal terminals CSs of shift register units SR9, SR10, SR11, SR12, SR13, SR14, SR15 and SR16. “in” represents an input signal of an input signal terminal IN, ck1 represents a first clock signal of a first clock signal terminal CK1, ck2 represents a second clock signal of a second clock signal terminal CK2, cs1 represents a first output control signal of an output control signal terminal CS, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, out8 represents a gate scanning signal of a driving output terminal OUT in an eighth shift register unit SR8, out9 represents a gate scanning signal of a driving output terminal OUT in a ninth shift register unit SR9, out10 represents a gate scanning signal of a driving output terminal OUT in a tenth shift register unit SR10, out11 represents a gate scanning signal of a driving output terminal OUT in an eleventh shift register unit SR11, out12 represents a gate scanning signal of a driving output terminal OUT in a twelfth shift register unit SR12, out13 represents a gate scanning signal of a driving output terminal OUT in a thirteenth shift register unit SR13, out14 represents a gate scanning signal of a driving output terminal OUT in a fourteenth shift register unit SR14, out15 represents a gate scanning signal of a driving output terminal OUT in a fifteenth shift register unit SR15, out16 represents a gate scanning signal of a driving output terminal OUT in a sixteenth shift register unit SR16, and out17 represents a gate scanning signal of a driving output terminal OUT in a seventeenth shift register unit SR17. A pulse width of the input signal “in” is 18H, a pulse width of one high level segment or one low level segment of each clock signal terminal is 2H, and pulse widths of a valid gate scanning signal output from a driving output terminal OUT and a valid cascade signal output from a cascaded output terminal OT are 18H.

A working process of a shift register unit provided in the embodiments of the present disclosure will be described below by taking a shift register unit structure shown in FIG. 21 as an example with reference to the signal timing diagram shown in FIG. 23.

As shown in FIG. 21, an example is taken for explanation in which all transistors are P-type transistors, a valid pulse signal of a first reference signal output from a first reference signal terminal VREF1 is a low level signal, a valid pulse signal of a second reference signal output from a second reference signal terminal VREF2 is a low level signal, a valid pulse signal of a third reference signal output from a third reference signal terminal VREF3 is a high level signal, a valid pulse signal of a fourth reference signal output from a fourth reference signal terminal VREF4 is a high level signal, a valid pulse signal of a fifth reference signal output from a fifth reference signal terminal VREF5 is a high level signal, a fixed voltage signal with a first electrical level V1 that a first output control signal cs-1 has is a high level signal, and a fixed voltage signal with a first electrical level V1 that a first output control signal cs-2 has is a high level signal.

Gate electrodes of a third transistor M3 and a seventh transistor M7 are coupled to the second reference signal terminal VREF2, and the second reference signal terminal VREF2 inputs a low level signal. Gate electrodes of a fourteenth transistor M14, a fifteenth transistor M15 and a twenty-eighth transistor M28 are coupled to the first reference signal terminal VREF1, and the first reference signal terminal VREF1 inputs a low level signal. Therefore, the third transistor M3, the seventh transistor M7, the fourteenth transistor M14, the fifteenth transistor M15 and the twenty-eighth transistor M28 are in a normally-on state. A gate electrode of a thirteenth transistor M13 is coupled to the fifth reference signal terminal VREF5, and the fifth reference signal terminal VREF5 inputs a high level signal. Therefore, the thirteenth transistor M13 is in a normally-off state. For ease of description, the states of the third transistor M3, the seventh transistor M7, the thirteenth transistor M13, the fourteenth transistor M14, and the fifteenth transistor M15 at any moment will not be analyzed hereinafter.

In a first stage H1, an input signal “in” is a low level signal, and a second clock signal ck2 and a first clock signal ck1 are periodically switched between high and low levels. A third node N3 is connected only to an input signal terminal IN, so that the third node N3 is always maintained at a low level. Under the control of a potential of the third node N3, a twelfth transistor M12 is turned on, the first node N1 is connected to the fourth reference signal terminal VREF4, and the first node N1 is maintained at a high level. Under the control of the potential of the first node N1, a first output transistor T1 and a first cascaded transistor T3 are turned off, the fourth reference signal terminal VREF4 is not connected to a cascaded output terminal OT, and an output control signal terminal CS is not connected to a driving output terminal OUT. Under the control of the potential of the third node N3, a second cascaded transistor T4 and a second output transistor T2 are turned on, the first reference signal terminal VREF1 is connected to the cascaded output terminal OT, and the first reference signal terminal VREF1 is connected to the driving output terminal OUT. The cascaded output terminal OT outputs a low level signal, and the driving output terminal OUT outputs a low level signal.

In a second stage H2, the input signal “in” is a high level signal, the second clock signal ck2 provides a high level signal, and the first clock signal ck1 provides a low level signal. A first transistor M1 and a sixth transistor M6 are turned on, and the third node N3 is maintained in a high level state. Under the control of the potential of the third node N3, a second transistor M2, the twelfth transistor M12, the second cascaded transistor T4 and the second output transistor T2 are turned off. The second cascaded transistor T4 and the second output transistor T2 are turned off, the first reference signal terminal VREF1 is not connected to the cascaded output terminal OT, and the first reference signal terminal VREF1 is not connected to the driving output terminal OUT. Under the control of the first clock signal ck1, a ninth transistor M9 is turned on, the second reference signal terminal VREF2 is connected to a fourth node N4, and the fourth node N4 is maintained at a low level. Under the control of the fourth node N4, a fourth transistor M4 is turned on. Under the control of the second clock signal ck2, a fifth transistor M5 is turned off. A first node N1 is maintained at a high level. The first cascaded transistor T3 and the first output transistor T1 are turned off. The fourth reference signal terminal VREF4 is not connected to the cascaded output terminal OT. The output signal control terminal CS is not connected to the driving output terminal OUT. The cascaded output terminal OT is maintained to output a low level signal, and the driving output terminal OUT is maintained to output a low level signal.

In a third stage H3, the input signal “in” is a high level signal, and the second clock signal ck2 and the first clock signal ck1 are periodically switched between high and low levels. In a start stage of the third stage H3, the second clock signal ck2 provides a low level signal, and the first clock signal ck1 provides a high level signal. In this case, under the control of the first clock signal ck1, the first transistor M1 and the sixth transistor M6 are switched between turn-on and turn-off. The third node N3 is maintained in a high level state. The second cascaded transistor T4 and the second output transistor T2 are turned off. The first reference signal terminal VREF1 is not connected to the cascaded output terminal OT, and the first reference signal terminal VREF1 is not connected to the driving output terminal OUT. Under the control of the third node N3, the second transistor M2 is maintained to be turned off. Under the control of the first clock signal ck1, the ninth transistor M9 is switched between turn-on and turn-off, and the fourth node N4 is maintained in a low level state. Under the control of the fourth node N4, the fourth transistor M4 is maintained in a turn-on state. When the second clock signal ck2 is switched to a low level, the fifth transistor M5 is turned on, a second clock signal terminal CK2 is connected to the first node N1, and the first node N1 becomes at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT outputs a high level signal, and the driving output terminal OUT outputs a high level signal. When the second clock signal ck2 is switched to a high level, the fifth transistor M5 is turned off, and the first node N1 is maintained at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT is maintained to output a high level signal, and the driving output terminal OUT is maintained to output a high level signal.

In a fourth stage H4, the input signal “in” is a low level signal. The second clock signal ck2 provides a low level signal, and the first clock signal ck1 provides a high level signal. In this case, the first transistor M1 and the sixth transistor M6 are turned off, and the third node N3 is maintained at a high level. The second cascaded transistor T4 and the second output transistor T2 are turned off, the first reference signal terminal VREF1 is not connected to the cascaded output terminal OT, and the first reference signal terminal VREF1 is not connected to the driving output terminal OUT. The fourth node N4 is maintained at a low level. Under the control of the fourth node N4, the fourth transistor M4 is maintained in a turn-on state. The second clock signal ck2 is at a low level. The fifth transistor M5 is turned on. The second clock signal ck2 is connected to the first node N1. The first node N1 becomes at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT outputs a high level signal, and the driving output terminal OUT outputs a high level signal.

In a fifth stage H5, the second clock signal ck2 and the first clock signal ck1 are periodically switched between high and low levels. In a start stage of the fifth stage H5, the second clock signal ck2 provides a high level signal, and the first clock signal ck1 provides a low level signal. In this case, the first transistor M1 and the sixth transistor M6 are turned on, and the third node N3 is at a low level. Under the control of the potential of the third node N3, the twelfth transistor M12 is turned on, the first node N1 is connected to the fourth reference signal terminal VREF4, and the first node N1 is maintained at a high level. Under the control of a potential of the first node N1, the first cascaded transistor T3 and the first output transistor T1 are turned off, the fourth reference signal terminal VREF4 is not connected to the cascaded output terminal OT, and the output signal control terminal CS is not connected to the driving output terminal OUT. Under the control of the potential of the third node N3, the second cascaded transistor T4 and the second output transistor T2 are turned on, the first reference signal terminal VREF1 is connected to the cascaded output terminal OT, and the first reference signal terminal VREF1 is connected to the driving output terminal OUT. The cascaded output terminal OT outputs a low level signal, and the driving output terminal OUT outputs a low level signal. In a subsequent stage, the third node N3 is maintained at a level, the cascaded output terminal OT is maintained to output a low level signal, and the driving output terminal OUT is maintained to output a low level signal.

The high level signal output from the cascaded output terminal OT is transmitted to an input signal terminal IN of a next GOA unit cascaded therewith as an input signal “in” of the next GOA unit cascaded therewith. Therefore, the next GOA unit will proceed to the stages H2-H5. A valid gate scanning signal output from a driving output terminal OUT and a valid cascade signal output from a cascaded output terminal OT of the next GOA unit are shifted backwards by 2H compared with a valid gate scanning signal output from a driving output terminal OUT and a valid cascade signal output from a cascaded output terminal OT of a previous GOA unit. The high level signal output from the driving output terminal OUT is a valid gate scanning signal. By analogy, full-screen scanning is implemented.

As shown in FIG. 21 and FIG. 22, the output control signal lines (such as CS-1 and CS-2 in FIG. 3) include: a first output control signal line CS-1 and a second output control signal line CS-2, where every eight adjacent shift register units in the shift register units constitute one shift register unit group, the first output control signal line CS-1 is coupled to output control signal terminals CSs of shift register units in odd-numbered shift register unit groups, and the second output control signal line CS-2 is coupled to output control signal terminals CSs of shift register units in even-numbered shift register unit groups. In an example, the first output control signal line CS-1 is coupled to output control signal terminals CSs of shift register units SR1, SR2, SR3, SR4, SR5, SR6, SR7 and SR8, and the second output control signal line CS-2 is coupled to output control signal terminals CSs of shift register units SR9, SR10, SR11, SR12, SR13, SR14, SR15 and SR16. “in” represents an input signal of an input signal terminal IN, ck1 represents a first clock signal of a first clock signal terminal CK1, ck2 represents a second clock signal of a second clock signal terminal CK2, cs1 represents a first output control signal of an output control signal terminal CS, out1 represents a gate scanning signal of a driving output terminal OUT in a first shift register unit SR1, out2 represents a gate scanning signal of a driving output terminal OUT in a second shift register unit SR2, out3 represents a gate scanning signal of a driving output terminal OUT in a third shift register unit SR3, out4 represents a gate scanning signal of a driving output terminal OUT in a fourth shift register unit SR4, out5 represents a gate scanning signal of a driving output terminal OUT in a fifth shift register unit SR5, out6 represents a gate scanning signal of a driving output terminal OUT in a sixth shift register unit SR6, out7 represents a gate scanning signal of a driving output terminal OUT in a seventh shift register unit SR7, out8 represents a gate scanning signal of a driving output terminal OUT in an eighth shift register unit SR8, out9 represents a gate scanning signal of a driving output terminal OUT in a ninth shift register unit SR9, out10 represents a gate scanning signal of a driving output terminal OUT in a tenth shift register unit SR10, out11 represents a gate scanning signal of a driving output terminal OUT in an eleventh shift register unit SR11, out12 represents a gate scanning signal of a driving output terminal OUT in a twelfth shift register unit SR12, out13 represents a gate scanning signal of a driving output terminal OUT in a thirteenth shift register unit SR13, out14 represents a gate scanning signal of a driving output terminal OUT in a fourteenth shift register unit SR14, out15 represents a gate scanning signal of a driving output terminal OUT in a fifteenth shift register unit SR15, out16 represents a gate scanning signal of a driving output terminal OUT in a sixteenth shift register unit SR16, and out17 represents a gate scanning signal of a driving output terminal OUT in a seventeenth shift register unit SR17. A pulse width of the input signal “in” is 18H, a pulse width of one high level segment or one low level segment of each clock signal terminal is 2H, and pulse widths of a valid gate scanning signal output from a driving output terminal OUT and a valid cascade signal output from a cascaded output terminal OT are 18H.

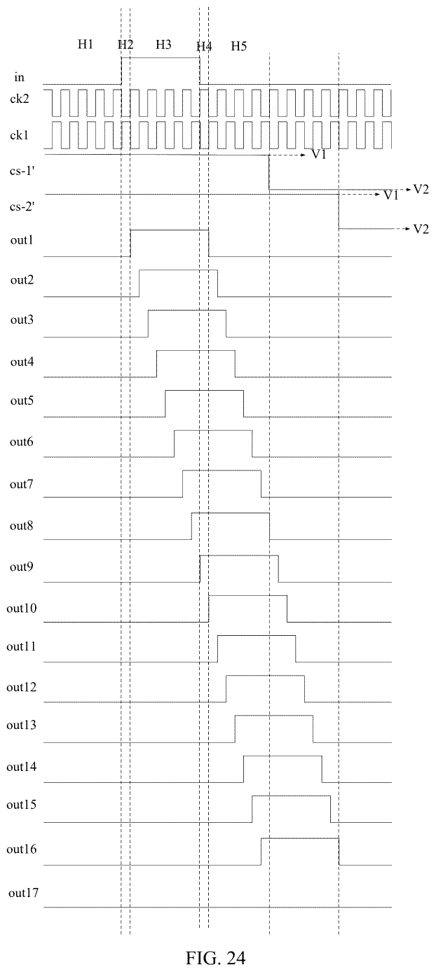

A working process of a shift register unit provided in the embodiments of the present disclosure will be described below by taking a shift register unit structure shown in FIG. 21 as an example with reference to the signal timing diagram shown in FIG. 24.

As shown in FIG. 21, an example is taken for explanation in which all transistors are P-type transistors, a valid pulse signal of a first reference signal output from a first reference signal terminal VREF1 is a low level signal, a valid pulse signal of a second reference signal output from a second reference signal terminal VREF2 is a low level signal, a valid pulse signal of a third reference signal output from a third reference signal terminal VREF3 is a high level signal, a valid pulse signal of a fourth reference signal output from a fourth reference signal terminal VREF4 is a high level signal, a valid pulse signal of a fifth reference signal output from a fifth reference signal terminal VREF5 is a high level signal, a fixed voltage signal with a first electrical level V1 that a second output control signal cs-1′ has is a high level signal, and a fixed voltage signal with a second electrical level V2 that the second output control signal cs-1′ has is a low level signal, a fixed voltage signal with a first electrical level V1 that a second output control signal cs-2′ has is a high level signal, and a fixed voltage signal with a second electrical level V2 that the second output control signal cs-2′ has is a low level signal.

Gate electrodes of a third transistor M3 and a seventh transistor M7 are coupled to the second reference signal terminal VREF2, and the second reference signal terminal VREF2 inputs a low level signal. Gate electrodes of a fourteenth transistor M14, a fifteenth transistor M15 and a twenty-eighth transistor M28 are coupled to the first reference signal terminal VREF1, and the first reference signal terminal VREF1 inputs a low level signal. Therefore, the third transistor M3, the seventh transistor M7, the fourteenth transistor M14, the fifteenth transistor M15 and the twenty-eighth transistor M28 are in a normally-on state. A gate electrode of a thirteenth transistor M13 is coupled to the fifth reference signal terminal VREF5, and the fifth reference signal terminal VREF5 inputs a high level signal. Therefore, the thirteenth transistor M13 is in a normally-off state. For ease of description, the states of the third transistor M3, the seventh transistor M7, the thirteenth transistor M13, the fourteenth transistor M14, and the fifteenth transistor M15 at any moment will not be analyzed hereinafter.

In a first stage H1, an input signal “in” is a low level signal, and a second clock signal ck2 and a first clock signal ck1 are periodically switched between high and low levels. A third node N3 is connected only to an input signal terminal IN, so that the third node N3 is always maintained at a low level. Under the control of a potential of the third node N3, a twelfth transistor M12 is turned on, the third node N3 is connected to the fourth reference signal terminal VREF4, and the third node N3 is maintained at a high level. Under the control of the potential of the third node N3, a first output transistor T1 and a first cascaded transistor T3 are turned off, the fourth reference signal terminal VREF4 is not connected to a cascaded output terminal OT, and an output control signal terminal CS is not connected to a driving output terminal OUT. Under the control of the potential of the third node N3, a second cascaded transistor T4 and a second output transistor T2 are turned on, the first reference signal terminal VREF1 is connected to the cascaded output terminal OT, and the first reference signal terminal VREF1 is connected to the driving output terminal OUT. The cascaded output terminal OT outputs a low level signal, and the driving output terminal OUT outputs a low level signal.

In a second stage H2, the input signal “in” is a high level signal, the second clock signal ck2 provides a high level signal, and the first clock signal ck1 provides a low level signal. A first transistor M1 and a sixth transistor M6 are turned on, and the third node N3 is maintained in a high level state. Under the control of the potential of the third node N3, a second transistor M2, the twelfth transistor M12, the second cascaded transistor T4 and the second output transistor T2 are turned off. The second cascaded transistor T4 and the second output transistor T2 are turned off, the first reference signal terminal VREF1 is not connected to the cascaded output terminal OT, and the first reference signal terminal VREF1 is not connected to the driving output terminal OUT. Under the control of the first clock signal ck1, a ninth transistor M9 is turned on, the second reference signal terminal VREF2 is connected to a fourth node N4, and the fourth node N4 is maintained at a low level. Under the control of the fourth node N4, a fourth transistor M4 is turned on. Under the control of the second clock signal ck2, a fifth transistor M5 is turned off. A first node N1 is maintained at a high level. The first cascaded transistor T3 and the first output transistor T1 are turned off. The fourth reference signal terminal VREF4 is not connected to the cascaded output terminal OT. The output signal control terminal CS is not connected to the driving output terminal OUT. The cascaded output terminal OT is maintained to output a low level signal, and the driving output terminal OUT is maintained to output a low level signal.

In a third stage H3, the input signal “in” is a high level signal, and the second clock signal ck2 and the first clock signal ck1 are periodically switched between high and low levels. In a start stage of the third stage H3, the second clock signal ck2 provides a low level signal, and the first clock signal ck1 provides a high level signal. In this case, under the control of the first clock signal ck1, the first transistor M1 and the sixth transistor M6 are switched between turn-on and turn-off. The third node N3 is maintained in a high level state. The second cascaded transistor T4 and the second output transistor T2 are turned off. The first reference signal terminal VREF1 is not connected to the cascaded output terminal OT, and the first reference signal terminal VREF1 is not connected to the driving output terminal OUT. Under the control of the third node N3, the second transistor M2 is maintained to be turned off. Under the control of the first clock signal ck1, the ninth transistor M9 is switched between turn-on and turn-off, and the fourth node N4 is maintained in a low level state. Under the control of the fourth node N4, the fourth transistor M4 is maintained in a turn-on state. When the second clock signal ck2 is switched to a low level, the fifth transistor M5 is turned on, a second clock signal terminal CK2 is connected to the first node N1, and the first node N1 becomes at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT outputs a high level signal, and the driving output terminal OUT outputs a high level signal. When the second clock signal ck2 is switched to a high level, the fifth transistor M5 is turned off, and the first node N1 is maintained at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT is maintained to output a high level signal, and the driving output terminal OUT is maintained to output a high level signal.

In a fourth stage H4, the input signal “in” is a low level signal. The second clock signal ck2 provides a low level signal, and the first clock signal ck1 provides a high level signal. In this case, the first transistor M1 and the sixth transistor M6 are turned off, and the third node N3 is maintained at a high level. The second cascaded transistor T4 and the second output transistor T2 are turned off, the first reference signal terminal VREF1 is not connected to the cascaded output terminal OT, and the first reference signal terminal VREF1 is not connected to the driving output terminal OUT. The fourth node N4 is maintained at a low level. Under the control of the fourth node N4, the fourth transistor M4 is maintained in a turn-on state. The second clock signal ck2 is at a low level. The fifth transistor M5 is turned on. The second clock signal ck2 is connected to the first node N1. The first node N1 becomes at a low level. The first cascaded transistor T3 and the first output transistor T1 are turned on, the fourth reference signal terminal VREF4 is connected to the cascaded output terminal OT, and the output signal control terminal CS is connected to the driving output terminal OUT. The cascaded output terminal OT outputs a high level signal, and the driving output terminal OUT outputs a high level signal.

In a fifth stage H5, the second clock signal ck2 and the first clock signal ck1 are periodically switched between high and low levels. In a start stage of the fifth stage H5, the second clock signal ck2 provides a high level signal, and the first clock signal ck1 provides a low level signal. In this case, the first transistor M1 and the sixth transistor M6 are turned on, and the third node N3 is at a low level. Under the control of the potential of the third node N3, the twelfth transistor M12 is turned on, the first node N1 is connected to the fourth reference signal terminal VREF4, and the first node N1 is maintained at a high level. Under the control of a potential of the first node N1, the first cascaded transistor T3 and the first output transistor T1 are turned off, the fourth reference signal terminal VREF4 is not connected to the cascaded output terminal OT, and the output signal control terminal CS is not connected to the driving output terminal OUT. Under the control of the potential of the third node N3, the second cascaded transistor T4 and the second output transistor T2 are turned on, the first reference signal terminal VREF1 is connected to the cascaded output terminal OT, and the first reference signal terminal VREF1 is connected to the driving output terminal OUT. The cascaded output terminal OT outputs a low level signal, and the driving output terminal OUT outputs a low level signal. In a subsequent stage, the third node N3 is maintained at a level, the cascaded output terminal OT is maintained to output a low level signal, and the driving output terminal OUT is maintained to output a low level signal.

The high level signal output from the cascaded output terminal OT is transmitted to an input signal terminal IN of a next GOA unit cascaded therewith as an input signal “in” of the next GOA unit cascaded therewith. Therefore, the next GOA unit will proceed to the stages H2-H5. A valid gate scanning signal output from a driving output terminal OUT and a valid cascade signal output from a cascaded output terminal OT of the next GOA unit are shifted backwards by 2H compared with a valid gate scanning signal output from a driving output terminal OUT and a valid cascade signal output from a cascaded output terminal OT of a previous GOA unit. The high level signal output from the driving output terminal OUT is a valid gate scanning signal. After a first shift register unit group outputs a valid gate scanning signal, and an eighth shift register unit SR8 outputs a complete valid gate scanning signal of 18H, the first output control signal cs-1′ is converted from a high level V1 to a low level V2, and then odd-numbered shift register unit groups output an invalid gate scanning signal. After a second shift register unit group outputs a valid gate scanning signal, and a sixteenth shift register unit SR16 outputs a complete valid gate scanning signal of 18H, the second output control signal cs-2′ is converted from a high level V1 to a low level V2, and then even-numbered shift register unit groups output an invalid gate scanning signal. So far, each shift register unit outputs a complete gate scanning signal of 18H or a complete invalid scanning signal of 18H. The situation where a valid gate scanning signal lower than 18H is output will not occur, which ensures the display quality of a display panel. Meanwhile, the output of a gate scanning signal of any one of the odd-numbered groups can be adjusted by means of the second output control signal cs-1′, and the output of a gate scanning signal of any one of the even-numbered groups can be adjusted by means of the second output control signal cs-2′. Cooperation of the two groups can implement adjustment to any region of the display panel, thereby realizing partition refresh of the display panel.

For example, in a display panel with 1024 rows of pixels, there are 512 shift register units in total, and each shift register unit controls two rows of pixels. Every eight adjacent shift register units constitute one group, and there are 64 groups in total. Output control signal terminals CSs of shift register units in the odd-numbered groups are coupled to a first output control signal line CS-1, and output control signal terminals CSs of shift register units in the even-numbered groups are coupled to a second output control signal line CS-2. When the first output control signal line CS-1 and the second output control signal line CS-2 are controlled to output a second output control signal, shift register units in first to thirty-second groups are enabled to output a valid gate scanning signal in each of 120 frames, and shift register units in thirty-third to sixty-fourth groups are enabled to output a valid gate scanning signal every other frame in 120 frames. A region controlled by first 512 rows of pixels in the display panel may be 120 Hz, and a region controlled by last 512 rows of pixels in the display panel may be 60 Hz, thereby realizing partition refresh. Of course, the first output control signal line CS-1 and the second output control signal line CS-2 may be controlled to output a second output control signal, so that any group outputs a valid gate scanning signal or an invalid gate scanning signal in any frame to realize partition refresh of the display panel.

In the embodiments of the present disclosure, by controlling a signal of an output control signal terminal, a gate scanning signal of a driving output terminal in an output circuit is controlled, so that scanning on any region of a display panel is controlled, and non-scanning on any region of the display panel is controlled, which saves power consumption, and reduces losses.

Other embodiments of the specification will be readily apparent to those skilled in the art after considering the specification and practicing the invention applied for herein. The specification is intended to cover any variations, uses, or adaptations of the specification, which follow the general principle of the specification and include common knowledge or conventional technical means in the art that are not applied for in the specification. The specification and examples are to be regarded as illustrative only. The true scope and spirit of the specification are pointed out by the following claims.

It is to be understood that the specification is not limited to the precise structures that have been described and shown in the drawings, and various modifications and changes can be made without departing from the scope thereof. The scope of the specification is to be limited only by the appended claims.

The above are only preferred embodiments of the specification, which are not intended to limit the specification. Any modification, equivalent replacement, improvement, etc., made within the spirit and principle of the specification shall be included in the protection scope of the specification.

1. A display panel, comprising:
a shift register unit and output control signal lines coupled to the shift register unit, wherein the output control signal lines are between the shift register unit coupled thereto and a display region of the display panel;
wherein the shift register unit comprises:
a shift register, configured to output a cascade signal through a cascaded output terminal;
an output circuit, coupled to the shift register, and configured to control a driving output terminal to output a gate scanning signal according to a signal of an output control signal terminal and a signal of a first reference signal terminal, wherein the output control signal terminal is coupled to one of the output control signal lines.

2. The display panel according to claim 1, wherein the output circuit comprises: a first output circuit and a second output circuit;
wherein the first output circuit is coupled to the cascaded output terminal or a first node in the shift register, and is configured to, in response to a signal of the cascaded output terminal or the first node, transmit the signal of the output control signal terminal to the driving output terminal;
wherein the second output circuit is coupled to a second node in the shift register, and is configured to, in response to a signal of the second node, transmit the signal of the first reference signal terminal to the driving output terminal.

3. The display panel according to claim 2, wherein the first output circuit comprises: a first output transistor;
wherein a gate electrode of the first output transistor is coupled to the cascaded output terminal or the first node, a first electrode of the first output transistor is coupled to the output control signal terminal, and a second electrode of the first output transistor is coupled to the driving output terminal.

4. The display panel according to claim 2, wherein the second output circuit comprises: a second output transistor;
wherein a gate electrode of the second output transistor is coupled to the second node, a first electrode of the second output transistor is coupled to the first reference signal terminal, and a second electrode of the second output transistor is coupled to the driving output terminal.

5. The display panel according to claim 2, wherein the shift register comprises:
an input sub-circuit, configured to, in response to a signal of a first clock signal terminal, provide a signal of an input signal terminal to a third node;
a control sub-circuit, configured to control signals of the first node and the second node, and provide a signal of the third node to the first node or the second node;
a cascaded sub-circuit, configured to, in response to the signals of the first node and the second node, enable the cascaded output terminal to output the cascade signal.

6. The display panel according to claim 5, wherein the input sub-circuit comprises: a first transistor;
wherein a gate electrode of the first transistor is coupled to the first clock signal terminal, a first electrode of the first transistor is coupled to the input signal terminal, and a second electrode of the first transistor is coupled to the third node.

7. The display panel according to claim 5, wherein the control sub-circuit comprises: a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, a first capacitor, a second capacitor, a third capacitor and a fourth capacitor; wherein:
a gate electrode of the second transistor is coupled to the third node, a first electrode of the second transistor is coupled to the first clock signal terminal, and a second electrode of the second transistor is coupled to a fourth node;
a gate electrode of the third transistor is coupled to a second reference signal terminal, a first electrode of the third transistor is coupled to the fourth node, and a second electrode of the third transistor is coupled to a gate electrode of the fourth transistor;
a first electrode of the fourth transistor is coupled to a second clock signal terminal, and a second electrode of the fourth transistor is coupled to a first electrode of the fifth transistor;
a gate electrode of the fifth transistor is coupled to the second clock signal terminal, and a second electrode of the fifth transistor is coupled to the first node;
a gate electrode of the sixth transistor is coupled to the first clock signal terminal, a first electrode of the sixth transistor is coupled to the input signal terminal, and a second electrode of the sixth transistor is coupled to a first electrode of the seventh transistor;
a gate electrode of the seventh transistor is coupled to the second reference signal terminal, and a second electrode of the seventh transistor is coupled to a fifth node;
a gate electrode of the eighth transistor is coupled to the fifth node, a first electrode of the eighth transistor is coupled to the fifth node, and a second electrode of the eighth transistor is coupled to the second node;
a gate electrode of the ninth transistor is coupled to the first clock signal terminal, a first electrode of the ninth transistor is coupled to the second reference signal terminal, and a second electrode of the ninth transistor is coupled to a gate electrode of the tenth transistor;
a first electrode of the tenth transistor is coupled to a third reference signal terminal, and a second electrode of the tenth transistor is coupled to a sixth node;
a gate electrode of the eleventh transistor is coupled to the fifth node, a first electrode of the eleventh transistor is coupled to the sixth node, and a second electrode of the eleventh transistor is coupled to the second clock signal terminal;
a gate electrode of the twelfth transistor is coupled to a first electrode of the fifteenth transistor, a first electrode of the twelfth transistor is coupled to the first node, and a second electrode of the twelfth transistor is coupled to a fourth reference signal terminal;
a gate electrode of the thirteenth transistor is coupled to a fifth reference signal terminal, a first electrode of the thirteenth transistor is coupled to the fourth reference signal terminal, and a second electrode of the thirteenth transistor is coupled to a first electrode of the fourteenth transistor;
a gate electrode of the fourteenth transistor is coupled to the first reference signal terminal, and a second electrode of the fourteenth transistor is coupled to the first electrode of the fifteenth transistor;
a gate electrode of the fifteenth transistor is coupled to the first reference signal terminal, the first electrode of the fifteenth transistor is coupled to the third node, and a second electrode of the fifteenth transistor is coupled to the second node;
a first electrode of the first capacitor is coupled to the gate electrode of the fourth transistor, and a second electrode of the first capacitor is coupled to the second electrode of the fourth transistor;
a first electrode of the second capacitor is coupled to the sixth node, and a second electrode of the second capacitor is coupled to the second electrode of the seventh transistor;
a first electrode of the third capacitor is coupled to the fourth reference signal terminal, and a second electrode of the third capacitor is coupled to the first node;
a first electrode of the fourth capacitor is coupled to the cascaded output terminal, and a second electrode of the fourth capacitor is coupled to the first reference signal terminal.

8. The display panel according to claim 5, wherein the cascaded sub-circuit comprises: a first cascaded transistor and a second cascaded transistor;
wherein:
a gate electrode of the first cascaded transistor is coupled to the first node, a first electrode of the first cascaded transistor is coupled to a fourth reference signal terminal, and a second electrode of the first cascaded transistor is coupled to the cascaded output terminal;
a gate electrode of the second cascaded transistor is coupled to the second node, a first electrode of the second cascaded transistor is coupled to the cascaded output terminal, and a second electrode of the second cascaded transistor is coupled to the first reference signal terminal.

9. The display panel according to claim 5, wherein the input sub-circuit comprises: a sixteenth transistor and a seventeenth transistor;
wherein:
a gate electrode of the sixteenth transistor is coupled to the first clock signal terminal, a first electrode of the sixteenth transistor is coupled to the input signal terminal, and a second electrode of the sixteenth transistor is coupled to a seventh node;
a gate electrode of the seventeenth transistor is coupled to the first clock signal terminal, a first electrode of the seventeenth transistor is coupled to the seventh node, and a second electrode of the seventeenth transistor is coupled to the third node.

10. The display panel according to claim 5, wherein the control sub-circuit comprises: an eighteenth transistor, a nineteenth transistor, a twentieth transistor, a twenty-first transistor, a twenty-second transistor, a twenty-third transistor, a fifth capacitor and a sixth capacitor;
wherein:
a gate electrode of the eighteenth transistor is coupled to the cascaded output terminal, a first electrode of the eighteenth transistor is coupled to a third clock signal terminal, and a second electrode of the eighteenth transistor is coupled to a seventh node;
a gate electrode of the nineteenth transistor is coupled to the input signal terminal, a first electrode of the nineteenth transistor is coupled to the first reference signal terminal, and a second electrode of the nineteenth transistor is coupled to the second node;
a gate electrode of the twentieth transistor is coupled to the second node, a first electrode of the twentieth transistor is coupled to the first reference signal terminal, and a second electrode of the twentieth transistor is coupled to an eighth node;
a gate electrode of the twenty-first transistor is coupled to the second node, a first electrode of the twenty-first transistor is coupled to the eighth node, and a second electrode of the twenty-first transistor is coupled to the third node;
a gate electrode of the twenty-second transistor is coupled to the third node, a first electrode of the twenty-second transistor is coupled to the eighth node, and a second electrode of the twenty-second transistor is coupled to a sixth reference signal terminal;
a gate electrode of the twenty-third transistor is coupled to a fourth clock signal terminal, a first electrode of the twenty-third transistor is coupled to the second node, and a second electrode of the twenty-third transistor is coupled to the sixth reference signal terminal;
a first electrode of the fifth capacitor is coupled to the first reference signal terminal, and a second electrode of the fifth capacitor is coupled to the first electrode of the twenty-third transistor;
a first electrode of the sixth capacitor is coupled to the cascaded output terminal, and a second electrode of the sixth capacitor is coupled to the first node.

11. The display panel according to claim 5, wherein the cascaded sub-circuit comprises: a first cascaded transistor and a second cascaded transistor;
wherein:
a gate electrode of the first cascaded transistor is coupled to the first node, a first electrode of the first cascaded transistor is coupled to the cascaded output terminal, and a second electrode of the first cascaded transistor is coupled to a third clock signal terminal;
a gate electrode of the second cascaded transistor is coupled to the second node, a first electrode of the second cascaded transistor is coupled to the first reference signal terminal, and a second electrode of the second cascaded transistor is coupled to the cascaded output terminal.

12. The display panel according to claim 5, wherein the control sub-circuit comprises: a twenty-fourth transistor, a twenty-fifth transistor, a twenty-sixth transistor, a twenty-seventh transistor, a twenty-eighth transistor, a seventh capacitor and an eighth capacitor;
wherein:
a gate electrode of the twenty-fourth transistor is coupled to the first clock signal terminal, a first electrode of the twenty-fourth transistor is coupled to a seventh reference signal terminal, and a second electrode of the twenty-fourth transistor is coupled to the second node;
a gate electrode of the twenty-fifth transistor is coupled to the third node, a first electrode of the twenty-fifth transistor is coupled to the second node, and a second electrode of the twenty-fifth transistor is coupled to the first clock signal terminal;
a gate electrode of the twenty-sixth transistor is coupled to the second node, a first electrode of the twenty-sixth transistor is coupled to the first reference signal terminal, and a second electrode of the twenty-sixth transistor is coupled to a first electrode of the twenty-seventh transistor;
a gate electrode of the twenty-seventh transistor is coupled to a third clock signal terminal, and a second electrode of the twenty-seventh transistor is coupled to a first electrode of the twenty-eighth transistor;
a gate electrode of the twenty-eighth transistor is coupled to the seventh reference signal terminal, the first electrode of the twenty-eighth transistor is coupled to the third node, and a second electrode of the twenty-eighth transistor is coupled to the first node;
a first electrode of the seventh capacitor is coupled to the first reference signal terminal, and a second electrode of the seventh capacitor is coupled to the second node;
a first electrode of the eighth capacitor is coupled to the cascaded output terminal, and a second electrode of the eighth capacitor is coupled to the first node.

13. The display panel according to claim 7, wherein the control sub-circuit further comprises: a twenty-eighth transistor;
wherein a first electrode of the twenty-eighth transistor is coupled to the second electrode of the fifth transistor, a second electrode of the twenty-eighth transistor is coupled to the first node, and a gate electrode of the twenty-eighth transistor is coupled to the first reference signal terminal.

14. A display panel, comprising:
a base substrate, comprising a display region and a non-display region,
wherein the display region comprises:
sub-pixels;
scan lines, wherein each row of the sub-pixels is coupled to at least one of the scan lines, wherein the non-display region comprises:
a gate driving circuit, comprising shift register units in the display panel, wherein a driving output terminal of each of the shift register units is coupled to at least one of the scan lines;
wherein the shift register unit comprises:
a shift register, configured to output a cascade signal through a cascaded output terminal;
an output circuit, coupled to the shift register, and configured to control a driving output terminal to output a gate scanning signal according to a signal of an output control signal terminal and a signal of a first reference signal terminal, wherein the output control signal terminal is coupled to one of the output control signal lines.

15. The display panel according to claim 14, further comprising: output control signal lines coupled to the gate driving circuit, wherein an extension direction of each of the output control signal lines is same as an arrangement direction of the shift register units;
wherein the output control signal lines are between the gate driving circuit coupled thereto and the display region;
wherein, in two adjacent shift register units in the shift register units, an input signal terminal of a latter one of the adjacent shift register units is coupled to a cascaded output terminal of a former one of the adjacent shift register units;
wherein the output control signal lines comprise: a first output control signal line and a second output control signal line;
wherein the first output control signal line is coupled to output control signal terminals of odd-numbered shift register units, and the second output control signal line is coupled to output control signal terminals of even-numbered shift register units; or, every eight adjacent shift register units in the shift register units constitute one shift register unit group, wherein the first output control signal line is coupled to output control signal terminals of shift register units in odd-numbered shift register unit groups, and the second output control signal line is coupled to output control signal terminals of shift register units in even-numbered shift register unit groups;
wherein the display panel further comprises: output control auxiliary signal lines, wherein a first insulating layer is provided between the output control auxiliary signal lines and the output control signal lines;
wherein the output control auxiliary signal lines are in one-to-one correspondence with the output control signal lines, and each of the output control auxiliary signal lines and a corresponding one of the output control signal lines are coupled to each other by a first hole through the first insulating layer;
wherein the display panel further comprises: clock signal lines coupled to the gate driving circuit, wherein an extension direction of each of the clock signal lines is same as an arrangement direction of the shift register units;
wherein the clock signal lines are disposed on a side of the gate driving circuit coupled thereto away from the display region;
wherein orthographic projections of the output control signal lines on the base substrate are disposed between orthographic projections of the clock signal lines on the base substrate and the display region;
wherein an orthographic projection of the gate driving circuit on the base substrate is disposed between orthographic projections of the clock signal lines on the base substrate and orthographic projections of the output control signal lines on the base substrate, and the orthographic projections of the output control signal lines on the base substrate are disposed between the orthographic projection of the gate driving circuit on the base substrate and the display region.

16-23. (canceled)

24. The display panel according to claim 14, wherein an orthographic projection of a first output transistor on the base substrate is located between an orthographic projection of a first cascaded transistor on the base substrate and the display region; an orthographic projection of a second output transistor on the base substrate is located between an orthographic projection of a second cascaded transistor on the base substrate and the display region;
wherein a width of a channel of a first output transistor is greater than a width of a channel of a first cascaded transistor;
wherein the width of the channel of the first output transistor is not less than 100 μm;
wherein the width of the channel of the first cascaded transistor is not greater than 60 μm;
wherein a width of a channel of a second output transistor is greater than a width of a channel of a second cascaded transistor;
wherein the width of the channel of the second output transistor is not less than 100 μm;
wherein the width of the channel of the second cascaded transistor is not greater than 60 μm.

25-31. (canceled)

32. A display device, comprising:
the display panel according to claim 14;
a driving control circuit, coupled to the display panel, and configured to input a first output control signal to output control signal terminals of the shift register units when a full-screen driving mode is determined to be adopted, to cause the shift register units sequentially output gate scanning signals to drive scan lines row by row, and
configured to input a second output control signal to the output control signal terminals of the shift register units when a local driving mode is determined to be adopted, to cause some of the shift register units sequentially output gate scanning signals, and rest of the shift register units output invalid scanning signals.

33. A driving control method, comprising:
inputting a first output control signal to output control signal terminals of shift register units when a full-screen driving mode is adopted, to cause the shift register units sequentially output gate scanning signals to drive scan lines row by row; and
inputting a second output control signal to the output control signal terminals of the shift register units, to cause some of the shift register units sequentially output gate scanning signals, and rest of the shift register units output invalid scanning signals to drive some of the scan lines.

34. The driving control method according to claim 33, wherein the first output control signal is a fixed voltage signal with a first electrical level;
wherein the second output control signal comprises a fixed voltage signal portion with a first electrical level and a fixed voltage signal portion with a second electrical level, the fixed voltage signal portion with the first electrical level is input to some of the shift register units, and the fixed voltage signal portion with the second electrical level is input to rest of the shift register units.

35. (canceled)

36. The driving control method according to claim 33, wherein the first output control signal is a clock signal;
wherein the second output control signal comprises a clock signal portion and a fixed voltage signal portion with a first electrical level;
wherein the clock signal portion in the second output control signal is input to some of the shift register units, and the fixed voltage signal portion with the first electrical level in the second output control signal is input to rest of the shift register units.

37-38. (canceled)
